(19) United States
(12) Patent Application Publication
(10) Pub. No.: US 2026/0052689 A1
(43) Pub. Date: Feb. 19, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Wooyoung LEE, Suwon-si (KR); Junghwan LEE, Suwon-si (KR)

(73) Assignee: Samsung Electronics Co., Ltd., Suwon-si (KR)

(21) Appl. No.: 19/037,659

(22) Filed: Jan. 27, 2025

(30) Foreign Application Priority Data
Aug. 14, 2024 (KR) 10-2024-0108969

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device includes gate lines each having a pair of main gate portions and a bridge connection portion, dummy channel structures passing through the gate lines in a vertical direction, and a local word line cut structure passing through respective local regions of the gate lines in the vertical direction and intermittently extending in a first direction to define the width of the bridge connection portion in the first direction, wherein the dummy channel structures include first normal dummy channel structures facing the local word line cut structure in a second direction and each having a center on an imaginary straight line extending in the first direction, and at least one offset dummy channel structure facing the bridge connection portion in the second direction and having a center at a position shifted from the imaginary straight line toward the bridge connection portion in the second direction.

### CROSS-REFERENCE TO RELATED APPLICATION

This application is based on and claims priority under 35 U.S.C. § 119 to Korean Patent Application No. 10-2024-0108969, filed on Aug. 14, 2024, in the Korean Intellectual Property Office, the disclosure of which is incorporated by reference herein in its entirety.

### BACKGROUND

The inventive concepts relate to a semiconductor device and an electronic system including the semiconductor device, and more particularly, to a semiconductor device including a nonvolatile vertical memory device and an electronic system including the semiconductor device.

To meet the demands for semiconductor devices capable of storing a high amount of data and electronic systems including the same, proposed are semiconductor devices that include vertical memory devices including 3-dimensionally arranged memory cells to increase the data storage capacity of semiconductor devices.

### SUMMARY

The inventive concepts provide a semiconductor device, which has a structure configured for securing reliability and improving electronic characteristics by preventing (and/or reducing the potential for) structural defects, such as pattern collapse, during the process of fabricating the semiconductor device, even when the degree of integration increases in the semiconductor device including 3-dimensionally arranged memory cells.

The inventive concepts also provide an electronic system including a semiconductor device, which has a structure configured for securing reliability and improving electronic characteristics by preventing (and/or reducing the potential for) structural defects, such as pattern collapse, during the process of fabricating the semiconductor device, even when the degree of integration increases in the semiconductor device including 3-dimensionally arranged memory cells.

According to an aspect of the inventive concepts, there is provided a semiconductor device including a plurality of gate lines overlapping each other in a vertical direction, each of the plurality of gate lines having a pair of main gate portions and a bridge connection portion connecting the pair of main gate portions to each other, a plurality of dummy channel structures passing through the plurality of gate lines in the vertical direction, and a local word line cut structure passing through respective local regions of the plurality of gate lines in the vertical direction, the local word line cut structure intermittently extending in a first horizontal direction such that a width of the bridge connection portion is defined by the local word line cut structure in the first horizontal direction, wherein the plurality of dummy channel structures comprise a first dummy channel structure group, the first dummy channel structure group comprising first dummy channel structures in a line extending in the first horizontal direction, the first dummy channel structures adjacent to the local word line cut structure, and the first dummy channel structure group includes first normal dummy channel structures facing the local word line cut structure in a second horizontal direction that is orthogonal to the first horizontal direction, each of the first normal dummy channel structures having a center on an imaginary first straight line extending in the first horizontal direction, and at least one offset dummy channel structure facing the bridge connection portion in the second horizontal direction and having a center at a position shifted from the imaginary first straight line toward the bridge connection portion in the second horizontal direction.

According to another aspect of the inventive concepts, there is provided a semiconductor device including a plurality of gate lines extending across a memory cell area, a dummy channel area, and a connection area, the memory cell area, the dummy channel area, and the connection area sequentially arranged in a first horizontal direction in a memory cell block, the plurality of gate lines overlapping each other in a vertical direction, a plurality of channel structures passing through the plurality of gate lines in the vertical direction in the memory cell area, a plurality of dummy channel structures passing through the plurality of gate lines in the vertical direction in the dummy channel area, a pair of word line cut structures extending lengthwise in the first horizontal direction and defining a width of the memory cell block in a second horizontal direction, the second horizontal direction orthogonal to the first horizontal direction, and a local word line cut structure between the pair of word line cut structures, the local word line cut structure passing through respective local regions of the plurality of gate lines in the vertical direction and intermittently extending in the first horizontal direction, wherein each of the plurality of gate lines includes a pair of main gate portions respectively contacting the pair of word line cut structures, and a bridge connection portion connecting the pair of main gate portions to each other in the dummy channel area, the bridge connection portion having a width defined in the first horizontal direction by the local word line cut structure, the plurality of dummy channel structures in the dummy channel area includes a first dummy channel structure group including first dummy channel structures in a line in the first horizontal direction adjacent to the local word line cut structure, and the first dummy channel structure group includes first normal dummy channel structures facing the local word line cut structure in the second horizontal direction, each of the first normal dummy channel structures having a center on an imaginary first straight line extending in the first horizontal direction, and an offset dummy channel structure facing the bridge connection portion in the second horizontal direction and having a center at a position shifted from the imaginary first straight line toward the bridge connection portion in the second horizontal direction.

According to another aspect of the inventive concepts, there is provided an electronic system including a main substrate, a semiconductor device on the main substrate, and a controller on the main substrate and electrically connected to the semiconductor device, wherein the semiconductor device includes a plurality of gate lines overlapping each other in a vertical direction, a plurality of dummy channel structures passing through the plurality of gate lines in the vertical direction, and a local word line cut structure passing through respective local regions of the plurality of gate lines in the vertical direction and intermittently extending in a first horizontal direction, the plurality of dummy channel structures comprise a first dummy channel structure group, the first dummy channel structure group comprising first dummy channel structures in a line extending in the first horizontal direction, the first dummy channel structures adjacent to the local word line cut structure, and the first dummy channel structure group includes first normal dummy channel structures facing the local word line cut structure in a second horizontal direction that is orthogonal to the first horizontal direction, each of the first normal dummy channel structures having a center on an imaginary first straight line extending in the first horizontal direction, and at least one offset dummy channel structure facing the bridge connection portion in the second horizontal direction and having a center at a position shifted from the imaginary first straight line toward the bridge connection portion in the second horizontal direction.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some embodiments;

FIG. 2 is a plan view illustrating a schematic planar structure of a portion of a memory cell array of a semiconductor device according to some embodiments;

FIG. 3 is a schematic perspective view of a portion of a semiconductor device according to some embodiments;

FIG. 4 is an equivalent circuit diagram of a memory cell array of a semiconductor device according to some embodiments;

FIG. 5A is a plan view illustrating an example of a configuration of a region EX1 of FIG. 2;

FIG. 5B is a plan view illustrating an example of a configuration of a region EX2 of FIG. 2;

FIG. 6 is a plan view illustrating an example of a configuration of a region EX3 of FIG. 2;

FIG. 7 is a cross-sectional view of the region EX1 of FIG. 5A, taken along a line Y1-Y1′ of FIG. 5A;

FIG. 8 is a cross-sectional view of the region EX1 of FIG. 5A, taken along a line Y2-Y2′ of FIG. 5A;

FIG. 9 is a cross-sectional view of the region EX3 of FIG. 6, taken along a line X1-X1′ of FIG. 6;

FIG. 10 is an enlarged plan view of a region EX4 of FIG. 5A;

FIGS. 11 to 18 are plan views respectively illustrating semiconductor devices according to some embodiments;

FIG. 19 is a diagram schematically illustrating an electronic system including a semiconductor device according to some embodiments;

FIG. 20 is a diagram schematically illustrating an electronic system including a semiconductor device according to embodiments;

FIG. 21 is a cross-sectional view schematically illustrating semiconductor packages according to some embodiments;

FIG. 22 is a cross-sectional view schematically illustrating semiconductor packages according to some embodiments; and

FIGS. 23A to 34 are cross-sectional views illustrating a method of fabricating a semiconductor device according to some embodiments, and in particular, FIGS. 23A, 24A, 25A, 28A, and 31A are cross-sectional views each illustrating some components in a region corresponding to a cross-section taken along the line Y1-Y1′ of FIG. 5A, according to a sequence of processes, FIGS. 28B and 31B are cross-sectional views each illustrating some components in a region corresponding to a cross-section taken along the line Y2-Y2′ of FIG. 5A, according to a sequence of processes, and FIGS. 23B, 24B, 25B, 26, 27, 28C, 29, 30, 31C, 32, 33, and 34 are cross-sectional views each illustrating some components in a region corresponding to a cross-section taken along the line X1-X1′ of FIG. 6, according to a sequence of processes.

### DETAILED DESCRIPTION OF THE EMBODIMENTS

Hereinafter, embodiments of the inventive concepts will be described in detail with reference to the accompanying drawings. Like components are denoted by like reference numerals throughout the specification, and repeated descriptions thereof may be omitted.

Embodiments to be described are merely examples, and various modifications may be made from such embodiments. In the drawings, sizes of components in the drawings may be exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Additionally, spatially relative terms, such as “above”, “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

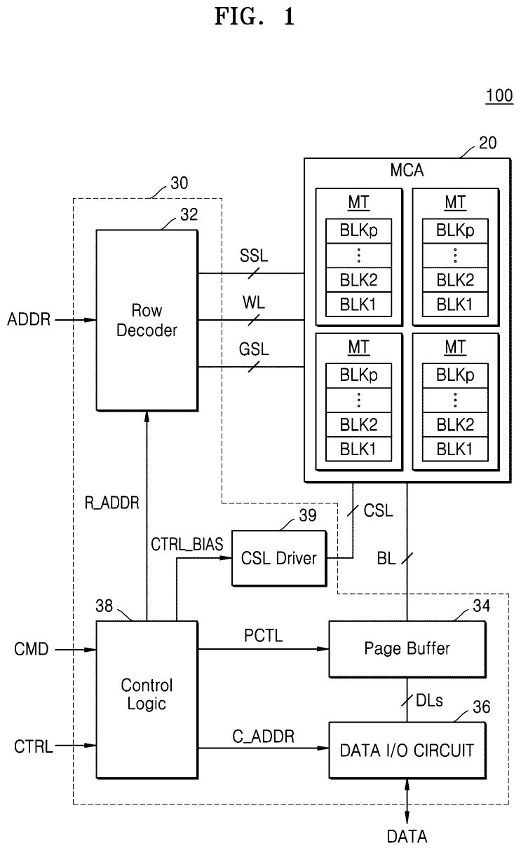

FIG. 1 is a block diagram of a semiconductor device 100 according to some embodiments.

Referring to FIG. 1, the semiconductor device 100 may include a memory cell array 20 and a peripheral circuit 30. The memory cell array 20 may include a plurality of mats MT. Each of the plurality of mats MT may include a plurality of memory cell blocks BLK1, BLK2, . . . , and BLKp. Each of the plurality of memory cell blocks BLK1, BLK2, . . . , and BLKp may include a plurality of memory cells. The plurality of memory cell blocks BLK1, BLK2, . . . , or BLKp may be, respectively, connected to the peripheral circuit 30 via a bit line BL, a word line WL, a string select line SSL, and a ground select line GSL. Herein, the memory cell array 20 may also be referred to as a memory cell array MCA.

The peripheral circuit 30 may include a row decoder 32, a page buffer 34, a data input/output circuit 36, a control logic 38, and a common source line driver 39. The peripheral circuit 30 may further include various circuits, such as a voltage generation circuit for generating various voltages required for operations of the semiconductor device 100, an error correction circuit for correcting errors in data read from the memory cell array 20, an input/output interface, and the like.

The memory cell array 20 may be connected to the row decoder 32 via the word line WL, the string select line SSL, and the ground select line GSL and may be connected to the page buffer 34 via the bit line BL. In the memory cell array 20, each of the plurality of memory cells, which are included in the plurality of memory cell blocks BLK1, BLK2, . . . , and BLKp, may include a flash memory cell. The memory cell array 20 may include a 3-dimensional memory cell array. The 3-dimensional memory cell array may include a plurality of NAND strings, and each of the plurality of NAND strings may include a plurality of memory cells respectively connected to a plurality of word lines WL that are vertically stacked.

The peripheral circuit 30 may be configured to receive an address ADDR, a command CMD, and a control signal CTRL from outside the semiconductor device 100 and may be configured to transmit data DATA to and receive data DATA from a device external to the semiconductor device 100.

The row decoder 32 may be configured to select at least one of the plurality of memory cell blocks BLK1, BLK2, . . . , and BLKp in response to the address ADDR from outside the semiconductor device 100 and may be configured to select the word line WL, the string select line SSL, and the ground select line GSL of the selected memory cell block. The row decoder 32 may be configured to transfer a voltage for performing a memory operation to the word line WL of the selected memory cell block.

The page buffer 34 may be connected to the memory cell array 20 via the bit line BL. The page buffer 34 may be configured to apply to the bit line BL a voltage according to the data DATA to be stored in the memory cell array 20 by operating as a write driver during a program operation and may be configured to sense the data DATA, which is stored in the memory cell array 20, by operating as a sense amplifier during a read operation. The page buffer 34 may operate according to a control signal PCTL provided by the control logic 38.

The data input/output circuit 36 may be connected to the page buffer 34 via a plurality of data lines DLs. During the program operation, the data input/output circuit 36 may receive the data DATA from a memory controller (not shown) and may provide program data DATA to the page buffer 34, based on a column address C_ADDR provided by the control logic 38. During the read operation, the data input/output circuit 36 may provide read data DATA stored in the page buffer 34 to the memory controller, based on the column address C_ADDR provided by the control logic 38.

The data input/output circuit 36 may transfer an address or a command, which is input thereto, to the control logic 38 or the row decoder 32. In at least some embodiments, peripheral circuit 30 may further include an electrostatic discharge (ESD) circuit (not shown) and/or a pull-up/pull-down driver (not shown).

The control logic 38 may be configured to receive the command CMD and the control signal CTRL from the memory controller. The control logic 38 may be configured to provide a row address R_ADDR to the row decoder 32 and may be configured to provide the column address C_ADDR to the data input/output circuit 36. The control logic 38 may be configured to generate various internal control signals, which are used in the semiconductor device 100, in response to the control signal CTRL. For example, when a memory operation, such as a program operation or an erase operation, is performed, the control logic 38 may adjust levels of voltages respectively provided to the word line WL and the bit line BL.

The common source line driver 39 may be connected to the memory cell array 20 via a common source line CSL. The common source line driver 39 may apply a common source voltage (for example, a power supply voltage) or a ground voltage to the common source line CSL, based on a control signal CTRL_BIAS of the control logic 38.

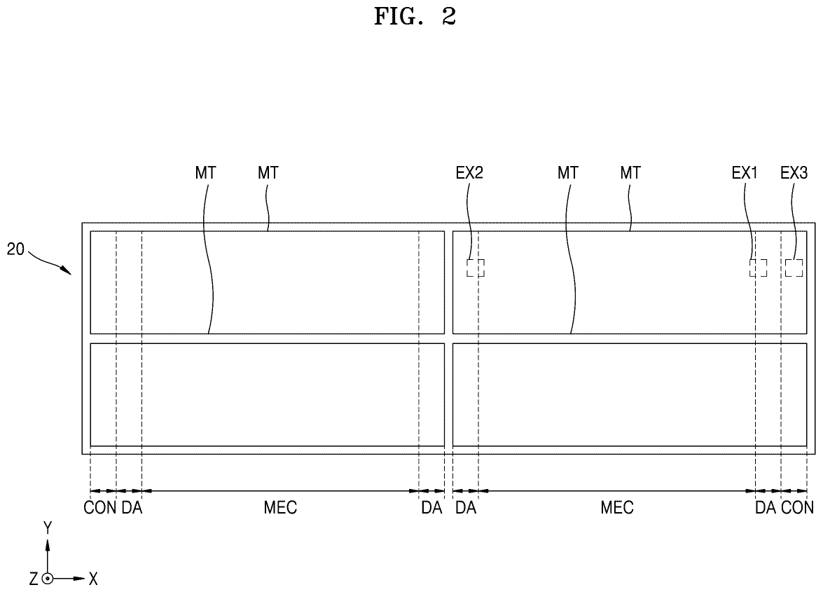

FIG. 2 is a plan view illustrating a schematic planar structure of a portion of the memory cell array 20 of the semiconductor device 100 according to some embodiments.

Referring to FIG. 2, the memory cell array 20 may include four mats MT respectively arranged in four quadrants that are included in a rectangular area. Each of the four mats MT may include a memory cell area MEC, a pair of dummy channel areas DA respectively arranged on both sides of the memory cell area MEC in reference to a first horizontal direction (an X direction), and a connection area CON arranged on one side of the memory cell area MEC in reference to the first horizontal direction (the X direction). One of the pair of dummy channel areas DA may be arranged between the memory cell area MEC and the connection area CON.

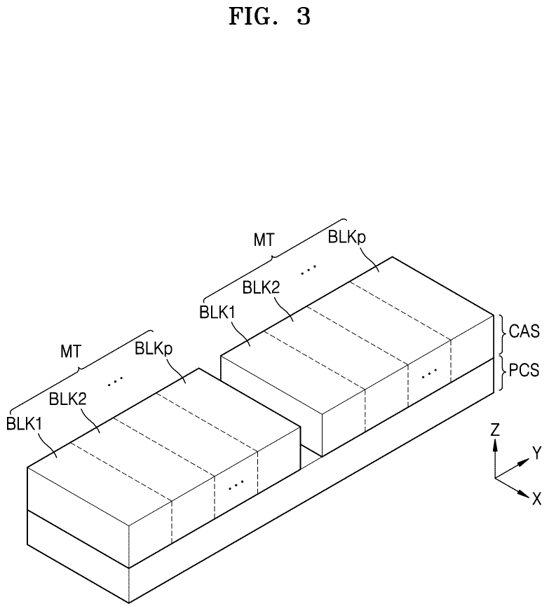

FIG. 3 is a schematic perspective view of a portion of the semiconductor device 100 according to some embodiments.

Referring to FIG. 3, the semiconductor device 100 may include a cell array structure CAS and a peripheral circuit structure PCS, which overlap each other in a vertical direction (a Z direction). The cell array structure CAS may correspond to the memory cell array 20 described with reference to FIGS. 1 and 2. The peripheral circuit structure PCS may correspond to the peripheral circuit 30 described with reference to FIG. 1.

In the cell array structure CAS, each of the plurality of mats MT may include a plurality of memory cell blocks BLK1, BLK2, . . . , and BLKp. Each of the plurality of memory cell blocks BLK1, BLK2, . . . , and BLKp may include 3-dimensionally arranged memory cells.

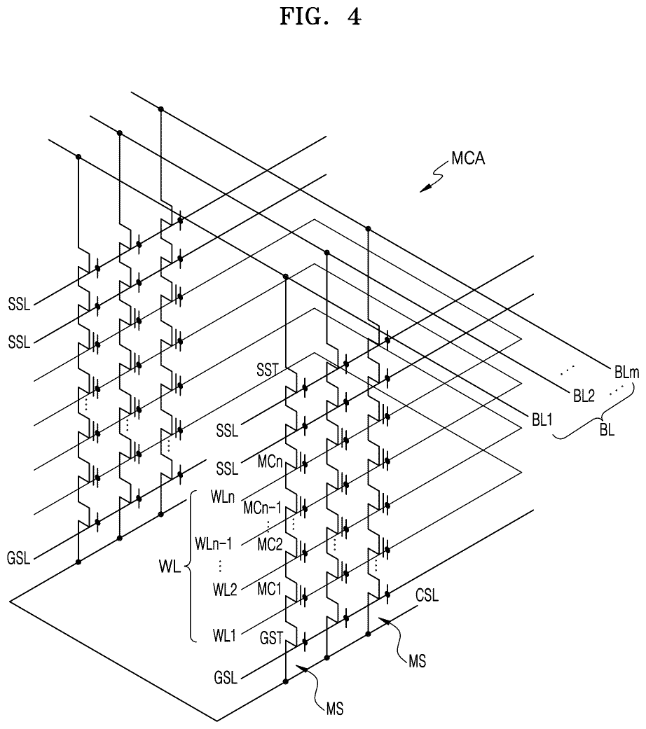

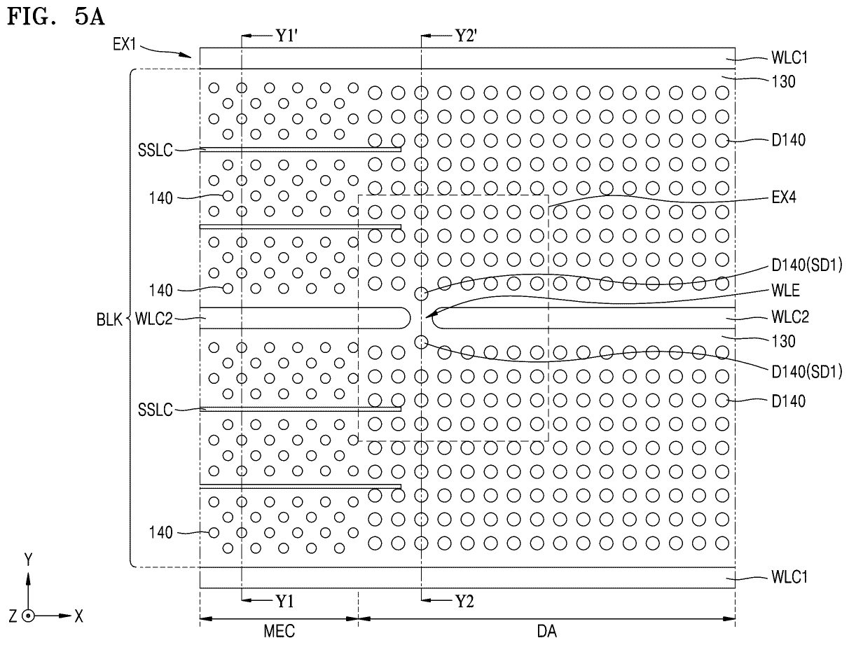

FIG. 4 is an equivalent circuit diagram of the memory cell array 20 of the semiconductor device 100 according to some embodiments. FIG. 4 illustrates an equivalent circuit diagram of a vertical NAND flash memory device having a vertical channel structure.

Referring to FIG. 4, the memory cell array 20 may include a plurality of memory cell strings MS. The memory cell array 20 may include a plurality of bit lines BL (e.g., BL1, BL2, . . . , and BLm), a plurality of word lines WL (e.g., WL1, WL2, . . . , WLn-1, and WLn), at least one string select line SSL, at least one ground select line GSL, and a common source line CSL. The plurality of memory cell strings MS may be formed between the plurality of bit lines BL and the common source line CSL. Although FIG. 4 illustrates an example in which each of the plurality of memory cell strings MS includes one ground select line GSL and two string select lines SSL, the inventive concepts are not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn-1, and MCn. A drain region of the string select transistor SST may be connected to a bit line BL, and a source region of the ground select transistor GST may be connected to the common source line CSL. The common source line CSL may be a region to which source regions of a plurality of ground select transistors GST are commonly connected.

The string select transistor SST may be connected to the string select line SSL, and the ground select transistor GST may be connected to the ground select line GSL. Each of the plurality of memory cell transistors MC1, MC2, . . . , MCn-1, and MCn may be connected to a word line WL.

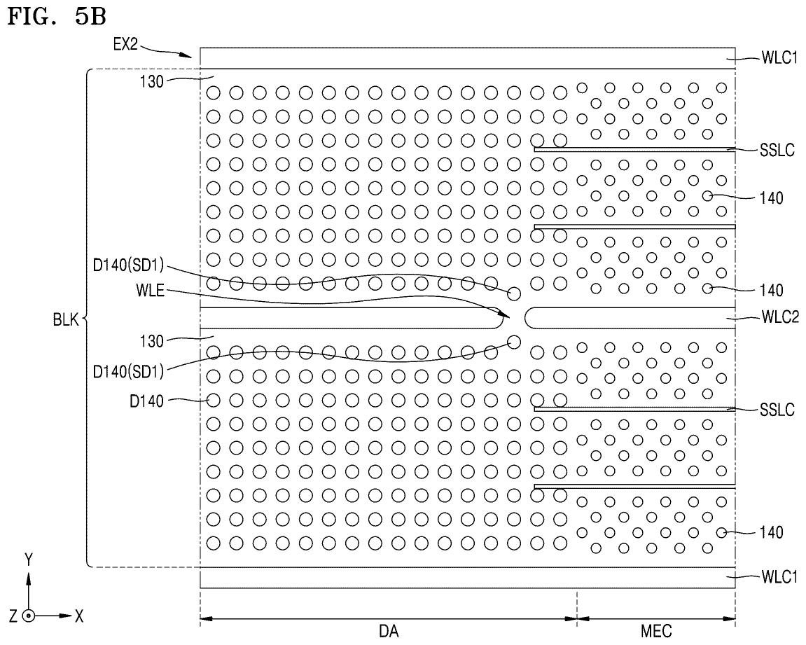

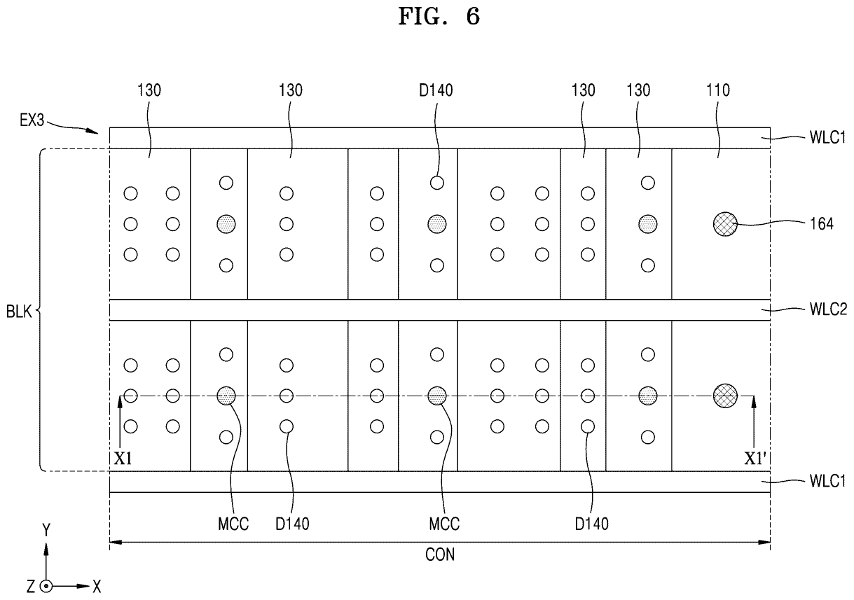

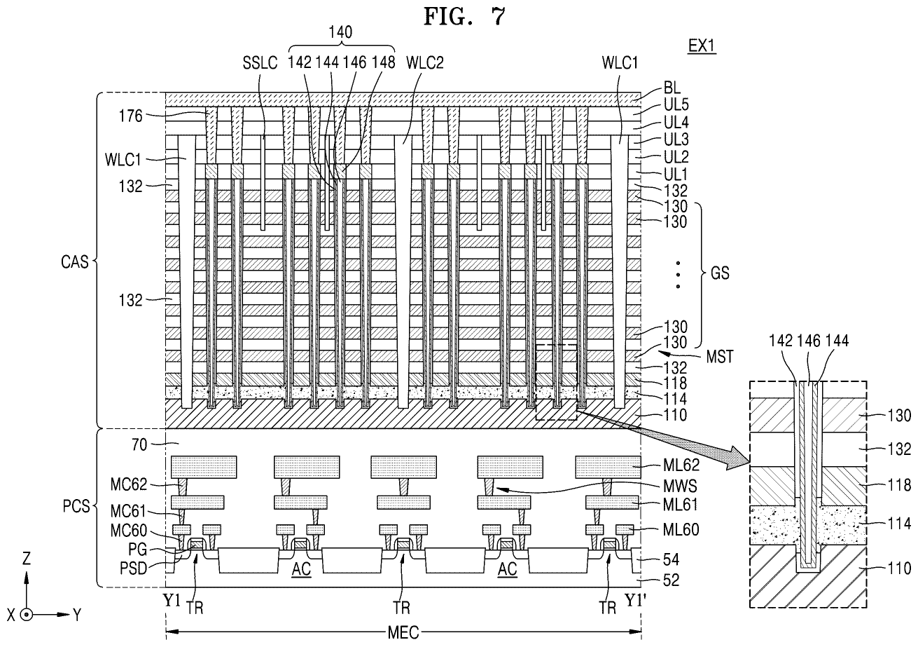

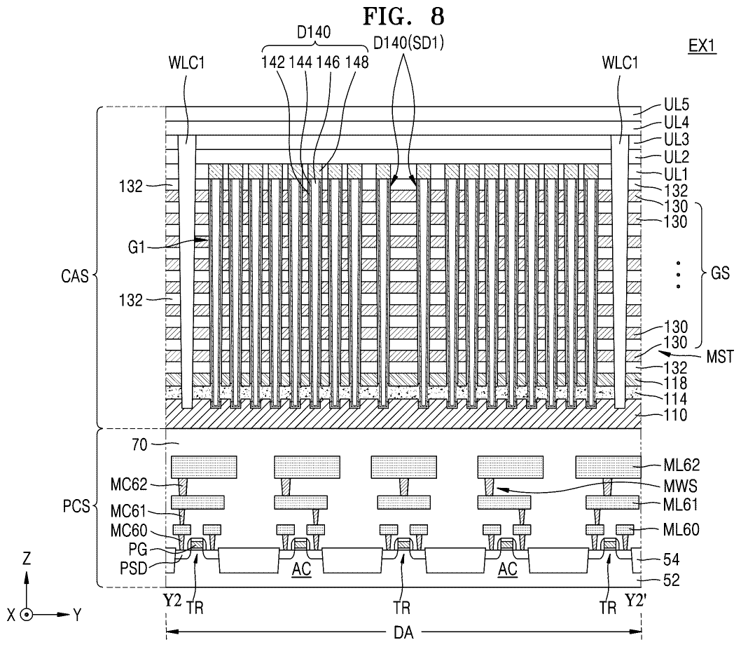

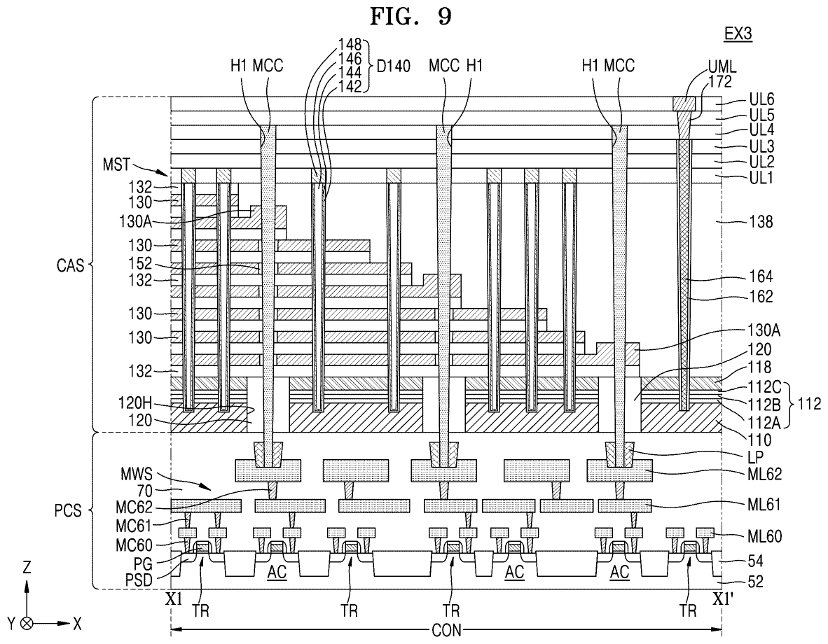

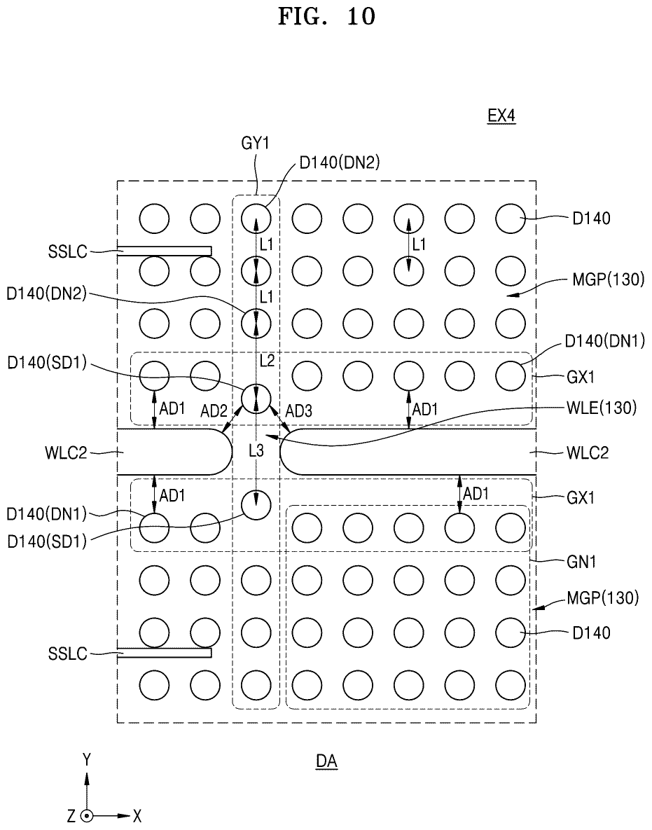

FIG. 5A is a plan view illustrating an example of a configuration of a region EX1 of FIG. 2, FIG. 5B is a plan view illustrating an example of a configuration of a region EX2 of FIG. 2, and FIG. 6 is a plan view illustrating an example of a configuration of a region EX3 of FIG. 2. FIG. 7 is a cross-sectional view of the region EX1 of FIG. 5A, taken along a line Y1-Y1′ of FIG. 5A, FIG. 8 is a cross-sectional view of the region EX1 of FIG. 5A, taken along a line Y2-Y2′ of FIG. 5A, and FIG. 9 is a cross-sectional view of the region EX3 of FIG. 6, taken along a line X1-X1′ of FIG. 6. FIG. 10 is an enlarged plan view of a region EX4 of FIG. 5A. The semiconductor device 100 is described in more detail with reference to FIGS. 5A to 10.

Referring to FIGS. 5A to 10, the cell array structure CAS of the semiconductor device 100 may include a plurality of plate common source lines 110 (see FIGS. 7 and 8) and a memory cell block BLK (see FIGS. 5A, 5B, and 6) arranged on each plate common source line 110. The memory cell block BLK may correspond to one of the plurality of memory cell blocks BLK1, BLK2, . . . , and BLKp described with reference to FIGS. 1 and 3. The peripheral circuit structure PCS (see FIGS. 7, 8, and 9) may be arranged under a plate common source line 110. The cell array structure CAS of the memory cell block BLK may be arranged to overlap the peripheral circuit structure PCS in the vertical direction (the Z direction) with the plate common source line 110 therebetween.

The memory cell block BLK of the cell array structure CAS may include one dummy channel area DA, a memory cell area MEC, another dummy channel area DA, and a connection area CON, which are sequentially arranged in the first horizontal direction (the X direction). The memory cell block BLK may include a memory stack structure MST extending in the first horizontal direction (the X direction) across the memory cell area MEC, the dummy channel areas DA, and the connection area CON.

The memory cell block BLK may include a plurality of gate lines 130 arranged on the plate common source line 110 to extend across the memory cell area MEC, a pair of dummy channel areas DA, and the connection area CON. The plurality of gate lines 130 may be stacked apart from each other in the vertical direction (the Z direction) to overlap each other in the vertical direction (the Z direction). In each of a plurality of memory stack structures MST, the plurality of gate lines 130 may constitute a gate stack GS. In each of the plurality of memory stack structures MST, the plurality of gate lines 130 may constitute the ground select line GSL, the plurality of word lines WL, and the string select line SSL, which are shown in FIG. 1.

In the connection area CON, the area occupied in the X-Y plane by the plurality of gate lines 130 may gradually decrease with an increasing distance from the plate common source line 110. In the memory cell area MEC and the pair of dummy channel areas DA, the area occupied in the X-Y plane by the plurality of gate lines 130 may be substantially equal or substantially similar regardless of the distance from the plate common source line 110.

In each of the plurality of gate lines 130, one edge portion in the first horizontal direction (the X direction) may constitute the connection area CON and the other edge portion in the first horizontal direction (the X direction) may constitute the dummy channel area DA.

As shown in FIGS. 5A to 8, a plurality of word line cut structures WLC1, which extend lengthwise in the first horizontal direction (the X direction) in the memory cell area MEC, the dummy channel areas DA, and the connection area CON, may be arranged on the plate common source line 110. The plurality of word line cut structures WLC1 may be apart from each other in a second horizontal direction (a Y direction). The memory cell block BLK may be arranged between a pair of word line cut structures WLC1 that are adjacent to each other from among the plurality of word line cut structures WLC1. The plurality of word line cut structures WLC1 may be arranged one-by-one on both sides of the memory cell block BLK in the second horizontal direction (the Y direction) to define the width of the memory cell block BLK in the second horizontal direction (the Y direction).

A local word line cut structure WLC2, which extends lengthwise in the first horizontal direction (the X direction), may be arranged in the memory cell block BLK. The local word line cut structure WLC2 may pass through respective local regions of the plurality of gate lines 130 in the vertical direction (the Z direction) between the pair of word line cut structures WLC1 defining one memory cell block BLK and may have a shape intermittently extending in the first horizontal direction (the X direction) in a plan view. For example, the local word line cut structure WLC2 may include a plurality of regions spaced apart from each other in the first horizontal direction (the X direction).

As shown in FIGS. 5A, 5B and 10, in the memory cell block BLK, each of the plurality of gate lines 130 may include a pair of main gate portions MGP, which respectively contact the pair of word line cut structures WLC1 adjacent to each other, and a bridge connection portion WLE connecting the pair of main gate portions MGP to each other. In the dummy channel area DA, the bridge connection portion WLE in each of the plurality of gate lines 130 of one memory cell block BLK may connect the pair of main gate portions MGP to each other. The bridge connection portion WLE may have a width defined in the first horizontal direction (the X direction) by the local word line cut structure WLC2.

In the memory cell block BLK, some regions of each of the plurality of gate lines 130 may be apart from or separated from each other in the second horizontal direction (the Y direction) by the local word line cut structure WLC2. Each of the word line cut structure WLC1 and the local word line cut structure WLC2 may include an insulating structure. The insulating structure may include, for example, silicon oxide, silicon nitride, silicon oxynitride, a low-k material, and/or the like. In some embodiments, the insulating structure may include, but is not limited to, a silicon oxide film, a silicon nitride film, a SiON film, a SiOCN film, a SiCN film, or a combination thereof. In some embodiments, at least a portion of the insulating structure may include an air gap. As used herein, the term “air” refers to the atmosphere or to other gases that may be present during a fabrication process.

As shown in FIGS. 7, 8, and 9, the cell array structure CAS may include a plate common source line 110, a first conductive plate 114, and a second conductive plate 118, which are arranged in the memory cell area MEC, and an insulating plate 112 arranged in the connection area CON, and a memory stack structure MST.

As shown in FIGS. 7 and 8, in the memory cell area MEC and the dummy channel area DA, the first conductive plate 114, the second conductive plate 118, and the memory stack structure MST may be stacked in the stated order on the plate common source line 110. The plate common source line 110, the first conductive plate 114, and the second conductive plate 118 may perform a function of a common source line CSL supplying currents to vertical memory cells that are included in the cell array structure CAS. As shown in FIG. 9, in the connection area CON, the insulating plate 112, the second conductive plate 118, and the edge portions of the plurality of gate lines 130 may be stacked in the stated order on the plate common source line 110.

In some embodiments, the plate common source line 110 may include a semiconductor material, such as polysilicon. Each of the first conductive plate 114 and the second conductive plate 118 may include a conductive material (e.g., a zero-bandgap material and/or the like) such as a doped polysilicon film, a metal film, or a combination thereof. The metal film may include, but is not limited to, tungsten (W).

The memory stack structure MST may include a gate stack GS. The gate stack GS may include a plurality of gate lines 130 extending to parallel to each other in a horizontal direction and overlapping each other in the vertical direction (the Z direction). Each of the plurality of gate lines 130 may include a conductive material, such as a metal, a metal silicide, an impurity-doped semiconductor, and/or a combination thereof. For example, each of the plurality of gate lines 130 may include a metal, such as tungsten, nickel, cobalt, or tantalum, a metal silicide, such as tungsten silicide, nickel silicide, cobalt silicide, or tantalum silicide, doped polysilicon, or a combination thereof.

A first insulating film 132 may be arranged between the second conductive plate 118 and the plurality of gate lines 130 and between each of the plurality of gate lines 130. The uppermost gate line 130 from among the plurality of gate lines 130 may be covered by the first insulating film 132. The first insulating film 132 may include an insulator, such as silicon oxide.

In the memory cell area MEC, the dummy channel areas DA, and the connection area CON, the plurality of word line cut structures WLC1 may be arranged on the plate common source line 110, and the local word line cut structure WLC2 may be arranged between the pair of word line cut structures WLC1 defining one memory cell block BLK. The word line cut structure WLC1 may continuously extend lengthwise in the first horizontal direction (the X direction), and the local word line cut structure WLC2 may intermittently extend lengthwise in the first horizontal direction (the X direction).

In the memory cell block BLK, the plurality of gate lines 130 constituting one gate stack GS may be stacked to overlap each other in the vertical direction (the Z direction). The plurality of gate lines 130 constituting one gate stack GS may include the ground select line GSL, the word line WL, and the string select line SSL, which have been described with reference to FIG. 1.

As shown in FIG. 7, two gate lines 130 at the top in the plurality of gate lines 130 may each be separated in the second horizontal direction (the Y direction) by a string select line cut structure SSLC, and a gate line 130 separated as such may constitute the string select line SSL described with reference to FIG. 1. Although FIG. 7 illustrates an example in which two string select line cut structures SSLC are formed in one gate stack GS, the inventive concepts are not limited to the example shown in FIG. 7. For example, one string select line cut structure SSLC may be formed in one gate stack GS. The string select line cut structure SSLC may include an insulating film. In some embodiments, the string select line cut structure SSLC may include an insulating film including an oxide film, a nitride film, or a combination thereof. In some embodiments, at least a portion of the string select line cut structure SSLC may include an air gap.

As shown in FIGS. 7, 8, and 9, the peripheral circuit structure PCS may include a substrate 52, a plurality of peripheral circuits on the substrate 52, and a multilayer wiring structure MWS for connecting the plurality of peripheral circuits to each other or connecting the plurality of peripheral circuits to components in the memory cell area MEC.

The substrate 52 may include a semiconductor substrate. For example, the substrate 52 may include Si, Ge, or SiGe. An active region AC may be defined in the substrate 52 by a device isolation film 54. A plurality of transistors TR constituting the plurality of peripheral circuits may be formed on the active region AC. Each of the plurality of transistors TR may include a gate PG and a plurality of ion-implanted regions PSD formed in the active region AC on both sides of the gate PG. Each of the plurality of ion-implanted regions PSD may constitute a source region or a drain region.

The plurality of peripheral circuits of the peripheral circuit structure PCS may include various circuits that are included in the peripheral circuit 30 described with reference to FIG. 1. For example, the plurality of peripheral circuits of the peripheral circuit structure PCS may include the row decoder 32, the page buffer 34, the data input/output circuit 36, the control logic 38, and the common source line driver 39, which are shown in FIG. 1.

The multilayer wiring structure MWS of the peripheral circuit structure PCS may include a plurality of wiring layers ML60, ML61, and ML62 and a plurality of contacts MC60, MC61, and MC62. At least some of the plurality of wiring layers ML60, ML61, and ML62 may be configured to be electrically connected to the transistors TR. The plurality of contacts MC60, MC61, and MC62 may be configured to respectively connect the plurality of transistors TR to some selected from the plurality of wiring layers ML60, ML61, and ML62. Each of the plurality of wiring layers ML60, ML61, and ML62 and the plurality of contacts MC60, MC61, and MC62 may include a metal, a conductive metal nitride, a metal silicide, or a combination thereof. For example, each of the plurality of wiring layers ML60, ML61, and ML62 and the plurality of contacts MC60, MC61, and MC62 may include a conductive material, such as tungsten, molybdenum, titanium, cobalt, tantalum, nickel, tungsten silicide, titanium silicide, cobalt silicide, tantalum silicide, or nickel silicide.

As shown in FIG. 9, a conductive landing pad LP may be arranged on a portion of the uppermost wiring layer ML62 from among the plurality of wiring layers ML60, ML61, and ML62. The conductive landing pad LP may include polysilicon. The plurality of transistors TR, the multilayer wiring structure MWS, and the conductive landing pad LP, which are included in the peripheral circuit structure PCS, may be covered by an interlayer dielectric 70. The interlayer dielectric 70 may include a silicon oxide film, a silicon nitride film, a SiON film, a SiOCN film, or a combination thereof. The plate common source line 110 may be arranged on the interlayer dielectric 70. The plate common source line 110, the insulating plate 112, the first conductive plate 114, and the second conductive plate 118 may each extend in the horizontal direction to cover the peripheral circuit structure PCS.

As shown in FIG. 9, in some regions of the connection area CON, a plurality of through-openings 120H may be formed to pass through the plate common source line 110, the insulating plate 112, and the second conductive plate 118 in the vertical direction (the Z direction). Each of the plurality of through-openings 120H may be filled with an insulating plug 120. The insulating plug 120 may include an insulating film, such as a silicon oxide film, a silicon nitride film, or a combination thereof.

As shown in FIG. 7, in the memory cell area MEC, a plurality of channel structures 140 may pass through, in the vertical direction (the Z direction), the plurality of gate lines 130, a plurality of first insulating films 132, the second conductive plate 118, the first conductive plate 114, and the plate common source line 110. The plurality of channel structures 140 may be arranged at certain intervals in the first horizontal direction (the X direction) and the second horizontal direction (the Y direction) to be apart from each other. As shown in FIGS. 5A and 5B, the plurality of channel structures 140 may have a honeycomb arrangement structure in which the channel structures 140 are arranged one-by-one at an internal center and respective vertices of an imaginary hexagon, in a plan view. Each of the plurality of channel structures 140 may include a gate dielectric film 142, a channel region 144, a buried insulating film 146, and a drain region 148.

The gate dielectric film 142 may include a tunneling dielectric film, a charge storage film, and a blocking dielectric film, which are formed in the stated order on the channel region 144. The tunneling dielectric film may include silicon oxide, hafnium oxide, aluminum oxide, zirconium oxide, tantalum oxide, and/or the like. The charge storage film is a region, in which electrons having passed through the tunneling dielectric film from the channel region 144 may be stored, and may include, e.g., silicon nitride, boron nitride, silicon boron nitride, impurity-doped polysilicon, or a combination thereof. The blocking dielectric film may include silicon oxide, silicon nitride, or a metal oxide having a dielectric constant that is greater than that of silicon oxide. The metal oxide may include, for example, hafnium oxide, aluminum oxide, zirconium oxide, tantalum oxide, or a combination thereof.

As shown in FIG. 7, the first conductive plate 114 may pass through a portion of the gate dielectric film 142 in the horizontal direction (the X direction and/or the Y direction) to contact the channel region 144. The gate dielectric film 142 may include a portion arranged at a higher level than the first conductive plate 114 and covering the sidewall of the channel region 144 and a portion arranged at a lower level than the first conductive plate 114 and covering the lower surface of the channel region 144. The channel region 144 may be apart from the plate common source line 110 with the gate dielectric film 142 therebetween. The sidewall of the channel region 144 may be in contact with the first conductive plate 114 and may be configured to be electrically connected to the first conductive plate 114.

As shown in FIG. 7, the channel region 144 may have a cylindrical shape. The channel region 144 may include doped polysilicon or undoped polysilicon. The buried insulating film 146 may fill an inner space of the channel region 144. The buried insulating film 146 may include an insulating material. For example, the buried insulating film 146 may include silicon oxide, silicon nitride, silicon oxynitride, or a combination thereof. In some embodiments, the buried insulating film 146 may be omitted. In this case, the channel region 144 may have a pillar structure having no inner space.

The drain region 148 may include a doped polysilicon film. A plurality of drain regions 148 may be insulated from each other by a first upper insulating film UL1. In the memory cell area MEC, the plurality of channel structures 140 and the first upper insulating film UL1 may be covered by a second upper insulating film UL2.

The string select line cut structure SSLC may pass through the first upper insulating film UL1, the second upper insulating film UL2, and a third upper insulating film UL3 in the vertical direction (the Z direction). The upper surface of the string select line cut structure SSLC, the upper surface of the word line cut structure WLC, and the upper surface of the third upper insulating film UL3 may extend at an approximately equal vertical level. A fourth upper insulating film UL4 and a fifth upper insulating film UL5 may be sequentially formed in the stated order on the string select line cut structure SSLC, the word line cut structure WLC, and the third upper insulating film UL3. Each of the first upper insulating film UL1, the second upper insulating film UL2, the third upper insulating film UL3, the fourth upper insulating film UL4, and the fifth upper insulating film UL5 may include an oxide film, a nitride film, or a combination thereof.

As shown in FIG. 7, in the memory cell area MEC of the memory stack structure MST, a plurality of bit lines BL may be arranged on the fifth upper insulating film UL5. The plurality of bit lines BL may extend in the second horizontal direction (the Y direction) to be parallel to each other. The plurality of channel structures 140 may be respectively connected to the plurality of bit lines BL via a plurality of contact plugs 176, which pass through the second upper insulating film UL2, the third upper insulating film UL3, the fourth upper insulating film UL4, and the fifth upper insulating film UL5.

As shown in FIG. 9, in the connection area CON, the insulating plate 112 and the second conductive plate 118 may be sequentially stacked in the stated order on the plate common source line 110. The insulating plate 112 may include a multilayer-structure insulating film including a first insulating thin film 112A, a second insulating thin film 112B, and a third insulating thin film 112C, which are sequentially stacked in the stated order on the plate common source line 110. In some embodiments, the first insulating thin film 112A and the third insulating thin film 112C may each include a silicon oxide film, and the second insulating thin film 112B may include a silicon nitride film.

In the connection area CON, each of the plurality of gate lines 130 may include a gate pad portion 130A having a thickness greater in the vertical direction (the Z direction) than those of other portions of the gate line 130. The gate pad portion 130A of the gate line 130 may be arranged in an edge portion, which is farthest from the memory cell area MEC, of the gate line 130. Although FIG. 9 illustrates only gate pad portions 130A that are respectively included in one-side end portions of some gate lines 130 from among the plurality of gate lines 130, the gate line 130 shown in FIG. 9 as not having a gate pad portion 130A may include a gate pad portion 130A arranged in other portions thereof not shown in FIG. 9.

In the connection area CON, an edge portion of each of the plurality of gate lines 130 and the plurality of first insulating films 132 may be covered by an interlayer dielectric 138. The interlayer dielectric 138 may include, but is not limited to, a silicon oxide film.

As shown in FIG. 9, a plurality of memory cell contacts MCC may be arranged in the connection area CON. Each of the plurality of memory cell contacts MCC may be arranged in a vertical hole H1 passing through at least some of the interlayer dielectric 138, the plurality of gate lines 130, and the plurality of first insulating films 132. Each of the plurality of memory cell contacts MCC may pass through at least one gate line 130, at least one first insulating film 132, the insulating plug 120, and the conductive landing pad LP in the vertical direction (the Z direction) and may be connected to each one wiring layer ML62 selected from the plurality of wiring layers ML60, ML61, and ML62 of the multilayer wiring structure MWS of the peripheral circuit structure PCS.

Each of the plurality of memory cell contacts MCC may be electrically connected to each a gate line 130 selected from the plurality of gate lines 130 and may not be electrically connected to other gate lines 130 except for the selected one gate line 130. Each of the plurality of memory cell contacts MCC may be in contact with the gate pad portion 130A of each one gate line 130 selected from the plurality of gate lines 130 and may be connected to the selected one gate line 130 via the gate pad portion 130A. The memory cell contact MCC in the vertical hole H1 may be apart from other gate lines 130 except for the selected one gate line 130 in the horizontal direction. An insulating ring 152 may be arranged between the memory cell contact MCC and a gate line 130 not connected to the memory cell contact MCC. In some embodiments, the insulating ring 152 may include, but is not limited to, a silicon oxide film.

As shown in FIGS. 5A, 5B, 6, 7, and 9, a plurality of dummy channel structures D140 may be arranged in the dummy channel area DA and the connection area CON. As shown in FIG. 8, in the dummy channel area DA, each of the plurality of dummy channel structures D140 may pass through the plurality of gate lines 130 and the plurality of first insulating films 132 in the vertical direction (the Z direction). As shown in FIG. 9, in the connection area CON, each of the plurality of dummy channel structures D140 may pass through at least some of the interlayer dielectric 138, the plurality of gate lines 130, and the plurality of first insulating films 132. In the connection area CON, each of the plurality of dummy channel structures D140 may pass through at least one of the plurality of gate lines 130. In the connection area CON, each of the plurality of dummy channel structures D140 may pass through at least one gate line 130, at least one first insulating film 132, the second conductive plate 118, and the insulating plate 112 in the vertical direction (the Z direction) and may pass through a portion of the plate common source line 110 in the vertical direction (the Z direction).

Similar to the channel structure 140, each of the plurality of dummy channel structures D140 may include a gate dielectric film 142, a channel region 144, a buried insulating film 146, and a drain region 148; however, the planar size of each of the plurality of dummy channel structures D140 may be greater than the planar size of the channel structure 140. In some embodiments, the plurality of dummy channel structures D140 may each include a silicon oxide plug. The number and arrangement shape of the dummy channel structures D140, which are shown in FIGS. 5A, 5B, 6, 7, and 9, are only examples, and the inventive concepts are not limited thereto. In the dummy channel area DA and the connection area CON, the plurality of dummy channel structures D140 may be variously arranged in various positions selected in the memory stack structure MST.

As shown in FIG. 9, in the connection area CON, the interlayer dielectric 138 may be covered by the first upper insulating film UL1. As shown in FIGS. 8 and 9, in the dummy channel area DA and the connection area CON, respective drain regions 148 of the plurality of dummy channel structures D140 may be insulated from each other by the first upper insulating film UL1. In the dummy channel area DA and the connection area CON, the plurality of dummy channel structures D140 and the first upper insulating film UL1 may be covered by the second upper insulating film UL2.

As shown in FIG. 9, a conductive plate contact 164 may be arranged in the connection area CON. The conductive plate contact 164 may extend in the vertical direction (the Z direction) to the plate common source line 110 through the third upper insulating film UL3, the second upper insulating film UL2, the first upper insulating film UL1, the interlayer dielectric 138, the second conductive plate 118, and the insulating plate 112. The sidewall of the conductive plate contact 164 may be covered by an insulating spacer 162. The fourth upper insulating film UL4 may cover the upper surface of each of the conductive plate contact 164 and the insulating spacer 162.

The plurality of memory cell contacts MCC may pass through the first upper insulating film UL1, the second upper insulating film UL2, the third upper insulating film UL3, and the fourth upper insulating film ULA. The upper surface of each of the plurality of memory cell contacts MCC may be covered by the fifth upper insulating film UL5 and the sixth upper insulating film UL6.

The conductive plate contact 164 may be connected to one upper wiring layer UML from among a plurality of upper wiring layers UML via a contact plug 172 passing through the fourth upper insulating film UL4 and the fifth upper insulating film UL5. The plurality of upper wiring layers UML may be arranged at the same (or at a substantially similar) vertical level as that of the plurality of bit lines BL arranged in the memory cell area MEC. A space between each of the plurality of upper wiring layers UML and a space between each of the plurality of bit lines BL may be filled with the sixth upper insulating film UL6. The sixth upper insulating film UL6 may include an oxide film, a nitride film, or a combination thereof.

The plurality of memory cell contacts MCC, the conductive plate contact 164, a plurality of contact plugs 172, and the plurality of upper wiring layers UML may each include a conductive material, such as tungsten, titanium, tantalum, copper, aluminum, titanium nitride, tantalum nitride, tungsten nitride, or a combination thereof.

In the connection area CON, the plate common source line 110, the insulating plate 112, the first conductive plate 114, and the second conductive plate 118 may extend in the horizontal direction (an X-Y plane direction) to cover the peripheral circuit structure PCS.

Each of the plurality of memory cell contacts MCC may be configured to be connected to at least one peripheral circuit selected from the plurality of peripheral circuits via the multilayer wiring structure MWS of the peripheral circuit structure PCS. Although FIGS. 7, 8 and 9 illustrate an example in which the multilayer wiring structure MWS includes three wiring layers in the vertical direction (the Z direction), the inventive concepts are not limited thereto. For example, the multilayer wiring structure MWS may include two wiring layers or four or more wiring layers.

Although FIG. 6 illustrates a configuration in which the plurality of memory cell contacts MCC are arranged in a line along a straight line in the first horizontal direction (the X direction), the inventive concepts is not limited thereto. A planar placement structure of each of the plurality of memory cell contacts MCC may be variously selected without departing from the scope of the inventive concepts.

As shown in FIGS. 5A, 5B, and 10, in the dummy channel area DA, the plurality of dummy channel structures D140 may include a first dummy channel structure group (for example, a first dummy channel structure group GX1 shown in FIG. 10) including first dummy channel structures that are arranged in a line in the first horizontal direction (the X direction) at a position adjacent to the local word line cut structure WLC2. The first dummy channel structures belonging to the first dummy channel structure group GX1, among the plurality of dummy channel structures D140, may include first normal dummy channel structures DN1, which face and are adjacent to the local word line cut structure WLC2 in the second horizontal direction (the Y direction), and an offset dummy channel structure SD1, which faces and is adjacent to the bridge connection portion WLE in the second horizontal direction (the Y direction). The first normal dummy channel structures DN1 of the first dummy channel structure group GX1 may each have a center on an imaginary first straight line extending in the first horizontal direction (the X direction) and may be arranged in a line in the first horizontal direction. The offset dummy channel structure SD1 may be arranged to be shifted from the imaginary first straight line toward the bridge connection portion WLE in the second horizontal direction (the Y direction). That is, in a plan view, the center of the offset dummy channel structure SD1 may be located away from the imaginary first straight line to be closer to the bridge connection portion WLE than to the imaginary first straight line.

In addition, as shown in FIGS. 5A, 5B, and 10, in the dummy channel area DA, the plurality of dummy channel structures D140 may include a second dummy channel structure group (for example, a second dummy channel structure group GY1 shown in FIG. 10) including second dummy channel structures that are arranged in a line along an imaginary second straight line extending in the second horizontal direction (the Y direction) across the bridge connection portion WLE of each of the plurality of gate lines 130. The second dummy channel structures belonging to the second dummy channel structure group GX1, among the plurality of dummy channel structures D140, may include two offset dummy channel structures SD1 and second normal dummy channel structures DN2, the second normal dummy channel structures DN2 being farther from the bridge connection portion WLE than the offset dummy channel structures SD1.

As shown in detail in FIG. 10, in each of the pair of main gate portions MGP, the minimum distance between an offset dummy channel structure SD1 and a second normal dummy channel structure DN2 closest to the offset dummy channel structure SD1 in the second horizontal direction (the Y direction) from among the second normal dummy channel structures DN2 may be greater than the minimum distance between two second normal dummy channel structures DN2 adjacent to each other in the second horizontal direction (the Y direction) from among the second normal dummy channel structures DN2. Therefore, in each of the pair of main gate portions MGP, a minimum distance L2 between the center of the offset dummy channel structure SD1 and the center of the second normal dummy channel structure DN2 closest to the offset dummy channel structures SD1 in the second horizontal direction (the Y direction) from among the second normal dummy channel structures DN2 may be greater than a minimum distance L1 between the centers of the two second normal dummy channel structures DN2 adjacent to each other in the second horizontal direction (the Y direction) from among the second normal dummy channel structures DN2.

An offset minimum distance AD2 or AD3 between the offset dummy channel structure SD1 and the local word line cut structure WLC2 may be selected from a range of +0.5 nm from a normal minimum distance AD1 between the local word line cut structure WLC2 and each of the first normal dummy channel structures DN1 belonging to the first dummy channel structure group GX1. For example, when the normal minimum distance AD1 is selected from a range of about 210 nm to about 250 nm, the offset minimum distance AD2 or AD3 may be selected from a range of about 209.5 nm to about 250.5 nm.

A minimum distance L3 between the centers of two offset dummy channel structures SD1 belonging to the second dummy channel structure group GY1 may be equal to or greater than the minimum distance L2 between the center of the offset dummy channel structure SD1 and the center of the second normal dummy channel structure DN2 closest to the offset dummy channel structures SD1.

In a plan view, other dummy channel structures D140 except for the second dummy channel structures of the second dummy channel structure group GY1, among the plurality of dummy channel structures D140, may be arranged at regular pitches in the first horizontal direction (the X direction) and the second horizontal direction (the Y direction) to form a matrix array structure. That is, in the dummy channel area DA, dummy channel structures D140 located to face the local word line cut structure WLC2 in the second horizontal direction (the Y direction), among the plurality of dummy channel structures D140, may be arranged at regular pitches in first horizontal direction (the X direction) and the second horizontal direction (the Y direction) to form a matrix array structure. For example, as shown in FIGS. 5A and 10, in the dummy channel area DA, the plurality of dummy channel structures D140 may include a normal dummy channel structure group GNI that includes third dummy channel structures arranged between the local word line cut structure WLC2 and each of the pair of word line cut structures WLC1 to pass through, in the vertical direction (the Z direction), at least one main gate portion MGP selected from a pair of main gate portions MGP of each of the plurality of gate lines 130. In a plan view, the third dummy channel structures of the normal dummy channel structure group GNI may be arranged at regular pitches in the first horizontal direction (the X direction) and the second horizontal direction (the Y direction) to form a matrix array structure.

According to the semiconductor device 100 described with reference to FIGS. 1 to 10, in the dummy channel area DA including the plurality of dummy channel structures D140 that support the plurality of gate lines 130 and the plurality of first insulating films 132, the offset dummy channel structure SD1 facing and adjacent to the bridge connection portion WLE in the second horizontal direction (the Y direction), among the plurality of dummy channel structures D140, may be out of the arrangement regularity of the first normal dummy channel structures DN1, which are arranged in a line in the first horizontal direction (the X direction), and may be arranged to be shifted in the second horizontal direction (the Y direction) toward the bridge connection portion WLE from the imaginary first straight line passing through the center of each of the first normal dummy channel structures DN1. Therefore, even when the planar area of the bridge connection portion WLE of each of the plurality of gate lines 130, which are arranged in a straight line in the first horizontal direction (the X direction) along with the local word line cut structure WLC2 intermittently extending lengthwise in the first horizontal direction (the X direction), is relatively large, the bridge connection portion WLE of each of the plurality of gate lines 130, and local regions overlapping the bridge connection portion WLE in the vertical direction (the Z direction), in each of the plurality of first insulating films 132, may be stably supported by the offset dummy channel structure SD1. In addition, during the process of fabricating the semiconductor device 100, before the plurality of gate lines 130 are formed, structural defects, such as a pattern collapse phenomenon in which the local regions overlapping a region corresponding to the bridge connection portion WLE, in each of the plurality of first insulating films 132, collapse, may be mitigated and/or prevented, and thus, the reliability and electrical characteristics of the semiconductor device 100 may improve.

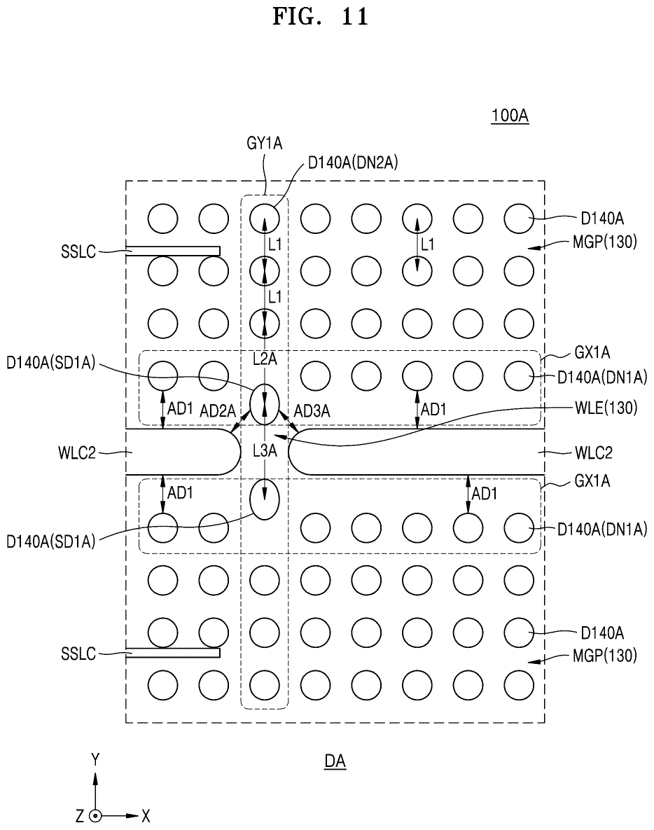

FIGS. 11 to 18 are plan views respectively illustrating semiconductor devices 100A, 200, 300, 300A, 400, 500, 500A, and 600 according to some embodiments. In FIGS. 11 to 18, the same reference numerals respectively denote the same members as in FIGS. 1 to 10, and here, and thereby the differences thereto are discussed, while repeated descriptions thereof may be omitted for brevity.

Referring to FIG. 11, the semiconductor device 100A includes a plurality of dummy channel structures D140A arranged in the dummy channel area DA.

The plurality of dummy channel structures D140A have substantially the same (and/or a substantially similar) configuration as the plurality of dummy channel structures D140 described with reference to FIGS. 5A to 10 except that the plurality of dummy channel structures D140A arranged in the dummy channel area DA of the semiconductor device 100A include a first dummy channel structure group GXIA, which includes first dummy channel structures arranged in a line in the first horizontal direction (the X direction) at a position adjacent to the local word line cut structure WLC2, and a second dummy channel structure group GY1A, which includes second dummy channel structures arranged in a line in the second horizontal direction (the Y direction) across the bridge connection portion WLE of each of the plurality of gate lines 130.

The first dummy channel structures belonging to the first dummy channel structure group GXIA, among the plurality of dummy channel structures D140A, may include first normal dummy channel structures DN1A, which face the local word line cut structure WLC2 in the second horizontal direction (the Y direction), and an offset dummy channel structure SD1A, which faces and is adjacent to the bridge connection portion WLE in the second horizontal direction (the Y direction). The first normal dummy channel structures DN1A of the first dummy channel structure group GXIA may each have a center on an imaginary first straight line extending in the first horizontal direction (the X direction) and may be arranged in a line in the first horizontal direction (the X direction). The offset dummy channel structure SD1A may be arranged to be shifted from the imaginary first straight line toward the bridge connection portion WLE in the second horizontal direction (the Y direction). That is, in a plan view, the center of the offset dummy channel structure SD1A may be arranged at a position deviating from the imaginary first straight line to be closer to the bridge connection portion WLE than to the imaginary first straight line.

In a plan view, the offset dummy channel structure SD1A may have a shape in which the size thereof in the second horizontal direction (the Y direction) is greater than the size thereof in the first horizontal direction (the X direction). In some embodiments, the offset dummy channel structure SD1A may have an elliptical planar shape. In a plan view, the size of the offset dummy channel structure SD1A in the second horizontal direction (the Y direction) may be greater than the size of each of the first normal dummy channel structures DN1A of the first dummy channel structure group GXIA in the second horizontal direction (the Y direction).

In addition, in the dummy channel area DA, the second dummy channel structures belonging to the second dummy channel structure group GY1A, among the plurality of dummy channel structures D140A, may include two offset dummy channel structures SD1A and second normal dummy channel structures DN2A, the second normal dummy channel structures DN2A being farther from the bridge connection portion WLE than the two offset dummy channel structures SD1A.

In a plan view, the size of the offset dummy channel structure SD1A in the second horizontal direction (the Y direction) may be greater than the size of each of the second normal dummy channel structures DN2A of the second dummy channel structure group GY1A in the second horizontal direction (the Y direction). The minimum distance between the offset dummy channel structure SD1A and a second normal dummy channel structure DN2A closest to the offset dummy channel structure SD1A in the second horizontal direction (the Y direction) from among the second normal dummy channel structures DN2A may be greater than the minimum distance two second normal dummy channel structures DN2A adjacent to each other in the second horizontal direction (the Y direction) from among the second normal dummy channel structures DN2A. Therefore, a minimum distance L2A between the center of the offset dummy channel structure SD1A and the center of the second normal dummy channel structure DN2A closest to the offset dummy channel structure SD1A from among the second normal dummy channel structures DN2A may be greater than the minimum distance L1 between two second normal dummy channel structures DN2A adjacent to each other in the second horizontal direction (the Y direction) from among the second normal dummy channel structures DN2A.

An offset minimum distance AD2A or AD3A between the offset dummy channel structure SD1A and the local word line cut structure WLC2 may be selected from a range of +0.5 nm from the normal minimum distance AD1 between the local word line cut structure WLC2 and each of the first normal dummy channel structures DN1A belonging to the first dummy channel structure group GX1A.

A minimum distance L3A between the centers of two offset dummy channel structures SD1A belonging to the second dummy channel structure group GY1A may be equal to or greater than the minimum distance L2A between the center of the offset dummy channel structures SD1A and the center of the second normal dummy channel structure DN2A closest to the offset dummy channel structures SD1A.

As noted above, more detailed configurations of the first normal dummy channel structures DN1A in the first dummy channel structure group GXIA and the second normal dummy channel structures DN2A in the second dummy channel structure group GY1A may otherwise be the same as (and/or substantially similar to) those of the first normal dummy channel structures DN1 and the second normal dummy channel structures DN2 described with reference to FIG. 10, respectively.

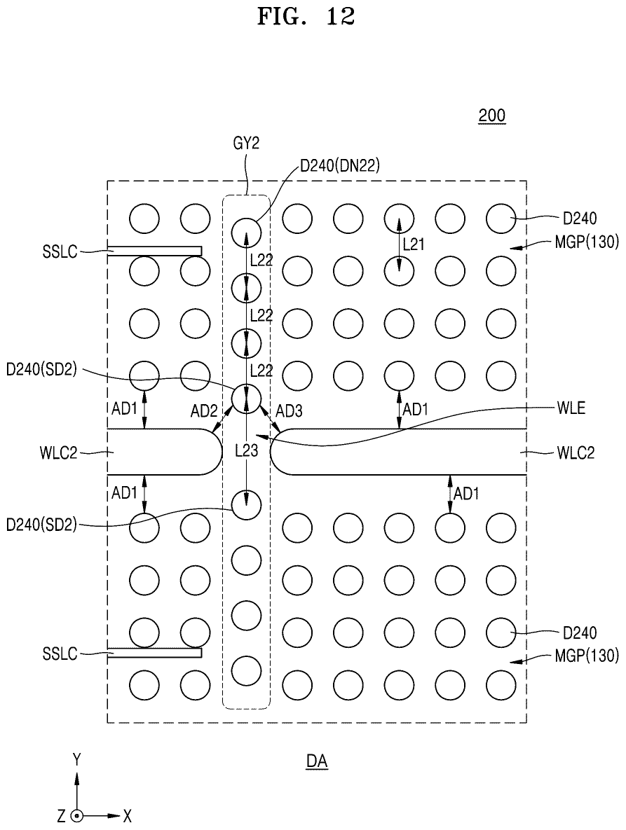

Referring to FIG. 12, the semiconductor device 200 includes a plurality of dummy channel structures D240 arranged in the dummy channel area DA.

The plurality of dummy channel structures D240 have substantially the same (or a substantially similar) configuration as the plurality of dummy channel structures D140 described with reference to FIGS. 5A to 10 except that the plurality of dummy channel structures D240 arranged in the dummy channel area DA of the semiconductor device 100A include a second dummy channel structure group GY2, which includes second dummy channel structures arranged in a line in the second horizontal direction (the Y direction) across the bridge connection portion WLE of each of the plurality of gate lines 130.

The second dummy channel structures belonging to the second dummy channel structure group GY2, among the plurality of dummy channel structures D240, may include two offset dummy channel structures SD2 facing and adjacent to the bridge connection portion WLE in the second horizontal direction (the Y direction).

In a plan view, in each of the pair of main gate portions MGP, the second dummy channel structures belonging to the second dummy channel structure group GY2 may include one offset dummy channel structure SD2 and second normal dummy channel structures DN22, the second normal dummy channel structures DN22 being farther from the bridge connection portion WLE than the offset dummy channel structure SD2. In each of the pair of main gate portions MGP, the offset dummy channel structure SD2 and the second normal dummy channel structures DN22, which are arranged in a line in the second horizontal direction (the Y direction), may be arranged at regular pitches in the second horizontal direction (the Y direction). That is, in one main gate portion MGP, a center-to-center distance L22 of adjacent two out of the offset dummy channel structure SD2 and the second normal dummy channel structures DN22 may be constant.

A center-to-center distance L23 of two offset dummy channel structures SD2, which are included in the second dummy channel structure group GY2 and apart from each other with the bridge connection portion WLE therebetween in the second horizontal direction (the Y direction), may be greater than the center-to-center distance L22 of adjacent two out of the second normal dummy channel structures DN22 in the second horizontal direction (the Y direction).

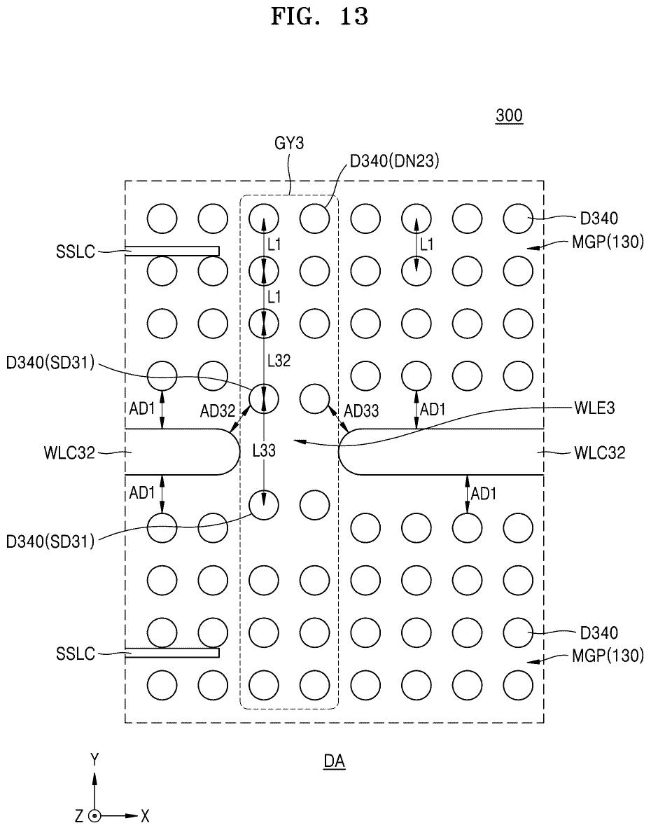

Referring to FIG. 13, the semiconductor device 300 has substantially the same (or a substantially similar) configuration as the semiconductor device 100 described with reference to FIGS. 1 to 10 except that the semiconductor device 300 includes a local word line cut structure WLC32, which passes through respective local regions of the plurality of gate lines 130 in the vertical direction (the Z direction) and has a shape intermittently extending in the first horizontal direction (the X direction) in a plan view, and a plurality of dummy channel structures D340, which are arranged in the dummy channel area DA to pass through the plurality of gate lines 130 in the vertical direction (the Z direction). The plurality of gate lines 130 may each include a bridge connection portion WLE3 connecting a pair of main gate portions MGP to each other, and the bridge connection portion WLE3 may have a width defined in the first horizontal direction (the X direction) by the local word line cut structure WLC32. The local word line cut structure WLC32 and the plurality of dummy channel structures D340 have the same (or a substantially similar) configurations as the local word line cut structure WLC2 and the plurality of dummy channel structures D140 described with reference to FIGS. 5A to 10, respectively. However, the plurality of dummy channel structures D340 arranged in the dummy channel area DA of the semiconductor device 300 include a second dummy channel structure group GY3 including second dummy channel structures arranged in a line in the second horizontal direction (the Y direction) across the bridge connection portion WLE3 of each of the plurality of gate lines 130.

The second dummy channel structures belonging to the second dummy channel structure group GY3, among the plurality of dummy channel structures D340, may include four offset dummy channel structures SD31 facing and adjacent to the bridge connection portion WLE3 in the second horizontal direction (the Y direction).

In a plan view, in each of the pair of main gate portions MGP, the second dummy channel structures belonging to the second dummy channel structure group GY3 may include two offset dummy channel structures SD31 and second normal dummy channel structures DN23, the second normal dummy channel structures DN23 being farther from the bridge connection portion WLE3 than the two offset dummy channel structures SD31.

In each of the pair of main gate portions MGP, the minimum distance in the second horizontal direction (the Y direction) between an offset dummy channel structure SD31 and a second normal dummy channel structure DN23 closest to the offset dummy channel structure SD31 in the second horizontal direction (the Y direction) from among the second normal dummy channel structures DN23 may be greater than the minimum distance between two second normal dummy channel structures DN23 adjacent to each other in the second horizontal direction (the Y direction) from among the second normal dummy channel structures DN23. Therefore, in each of the pair of main gate portions MGP, a minimum distance L32 in the second horizontal direction (the Y direction) between the center of the offset dummy channel structure SD31 and the center of the second normal dummy channel structure DN23 closest to the offset dummy channel structure SD31 in the second horizontal direction (the Y direction) from among the second normal dummy channel structures DN23 may be greater than a minimum distance L1 between the centers of two second normal dummy channel structures DN23 adjacent to each other in the second horizontal direction (the Y direction) from among the second normal dummy channel structures DN23.

The respective centers of two offset dummy channel structures SD31 arranged in a line in the second horizontal direction (the Y direction), among the four offset dummy channel structures SD31 belonging to the second dummy channel structure group GY3, may be arranged on a straight line extending in the second horizontal direction (the Y direction). A minimum distance L33 between the centers of the two offset dummy channel structures SD31 on the straight line in the second horizontal direction (the Y direction) may be equal to or greater than a minimum distance L32 between the center of the offset dummy channel structure SD31 and the center of the second normal dummy channel structure DN23 closest to the offset dummy channel structure SD31 in the second horizontal direction (the Y direction).

The respective centers of two offset dummy channel structures SD31 arranged in a line in the first horizontal direction (the X direction), among the four offset dummy channel structures SD31 belonging to the second dummy channel structure group GY3, may be arranged on a straight line extending in the first horizontal direction (the X direction).

The semiconductor device 300 has an offset minimum distance AD32 or AD33 between the offset dummy channel structure SD31 and the local word line cut structure WLC32. The semiconductor device 300 has a normal minimum distance AD1 between the local word line cut structure WLC32 and a dummy channel structure D340 facing and closest to the local word line cut structure WLC32 in the second horizontal direction (the Y direction). The offset minimum distance AD32 or AD33 may be selected from a range of ±0.5 nm from the normal minimum distance AD1.

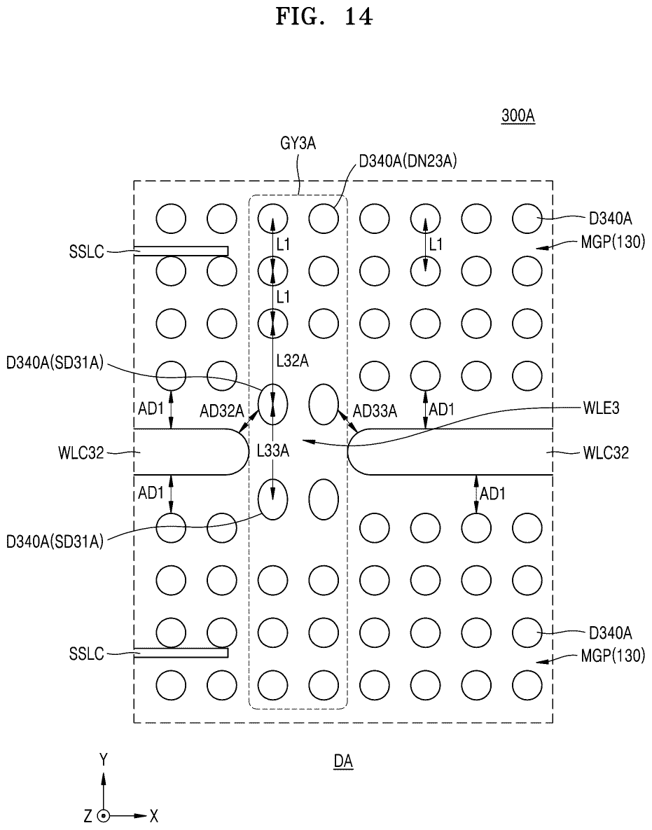

Referring to FIG. 14, the semiconductor device 300A has the same (or a substantially similar) configuration as the semiconductor device 300 described with reference to FIG. 13. However, the semiconductor device 300A includes a plurality of dummy channel structures D340A arranged in the dummy channel area DA.

The plurality of dummy channel structures D340A have the same (or a substantially similar) configuration as the plurality of dummy channel structures D340 described with reference to FIG. 13. However, the plurality of dummy channel structures D340A arranged in the dummy channel area DA of the semiconductor device 300A includes a second dummy channel structure group GY3A including second dummy channel structures arranged in a line in the second horizontal direction (the Y direction) across the bridge connection portion WLE3 of each of the plurality of gate lines 130.

The second dummy channel structures belonging to the second dummy channel structure group GY3A, among the plurality of dummy channel structures D340A, may include four offset dummy channel structures SD31A facing and adjacent to the bridge connection portion WLE3 in the second horizontal direction (the Y direction).

In a plan view, in each of the pair of main gate portions MGP, the second dummy channel structures belonging to the second dummy channel structure group GY3A may include two offset dummy channel structures SD31A and second normal dummy channel structures DN23A, the second normal dummy channel structures DN23A being farther from the bridge connection portion WLE3 than the two offset dummy channel structures SD31A.

In a plan view, an offset dummy channel structure SD31A may have a shape in which the size thereof in the second horizontal direction (the Y direction) is greater than the size thereof in the first horizontal direction (the X direction). In some embodiments, the offset dummy channel structure SD31A may have an elliptical planar shape. In a plan view, the size, in the second horizontal direction (the Y direction), of each of the four offset dummy channel structures SD31A belonging to the second dummy channel structure group GY3A may be greater than the size, in the second horizontal direction (the Y direction), of each of the second normal dummy channel structures DN23A.

The minimum distance in the second horizontal direction (the Y direction) between the offset dummy channel structure SD31A and a second normal dummy channel structure DN23A closest to the offset dummy channel structure SD31A in the second horizontal direction (the Y direction) from among the second normal dummy channel structures DN23A may be greater than the minimum distance in the second horizontal direction (the Y direction) between two second normal dummy channel structures DN23A adjacent to each other in the second horizontal direction (the Y direction) from among the second normal dummy channel structures DN23A. Therefore, a minimum distance L32A in the second horizontal direction (the Y direction) between the center of the offset dummy channel structure SD31A and the center of the second normal dummy channel structure DN23A closest to the offset dummy channel structure SD31A in the second horizontal direction (the Y direction) from among the second normal dummy channel structures DN23A may be greater than the minimum distance L1 between the centers of the two second normal dummy channel structures DN23A adjacent to each other in the second horizontal direction (the Y direction) from among the second normal dummy channel structures DN23A.

The semiconductor device 300A has an offset minimum distance AD32A or AD33A between the offset dummy channel structure SD31A and the local word line cut structure WLC32. The semiconductor device 300A has a normal minimum distance AD1 between the local word line cut structure WLC32 and a dummy channel structure D340A facing and closest to the local word line cut structure WLC32 in the second horizontal direction (the Y direction). The offset minimum distance AD32A or AD33A may be selected from a range of ±0.5 nm from the normal minimum distance AD1.

The respective centers of two offset dummy channel structures SD31A arranged in a line in the second horizontal direction (the Y direction), among the four offset dummy channel structures SD31A belonging to the second dummy channel structure group GY3A, may be arranged on a straight line extending in the second horizontal direction (the Y direction). A minimum distance L33A between the centers of the two offset dummy channel structures SD31A on the straight line in the second horizontal direction (the Y direction) may be equal to or greater than a minimum distance L32A between the center of the offset dummy channel structure SD31A and the center of the second normal dummy channel structure DN23A closest to the offset dummy channel structure SD31A.

The respective centers of two offset dummy channel structures SD31A arranged in a line in the first horizontal direction (the X direction), among the four offset dummy channel structures SD31 belonging to the second dummy channel structure group GY3A, may be arranged on a straight line extending in the first horizontal direction (the X direction).

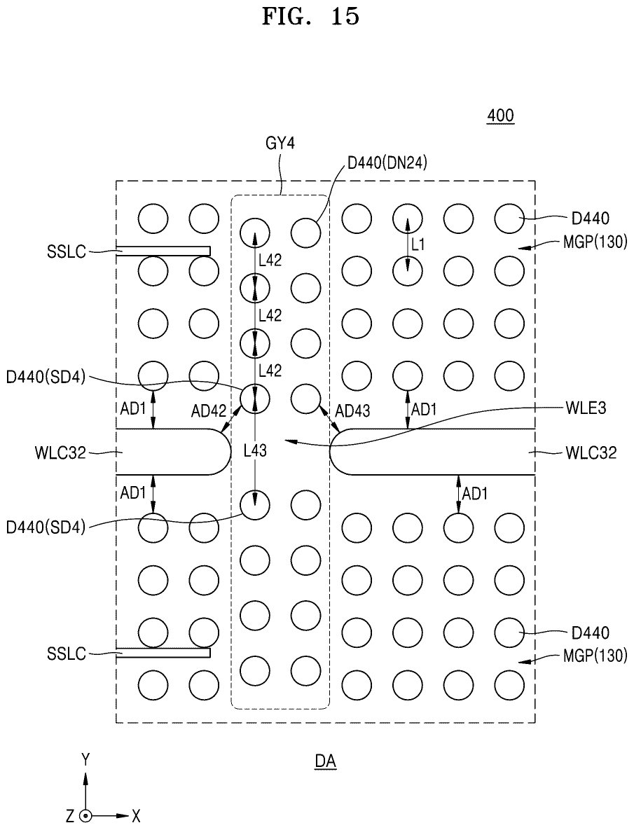

Referring to FIG. 15, the semiconductor device 400 has the same (or a substantially similar) configuration as the semiconductor device 300 described with reference to FIG. 13. However, the semiconductor device 400 includes a plurality of dummy channel structures D440 arranged in the dummy channel area DA.

The plurality of dummy channel structures D440 have substantially the same (or a substantially similar) configuration as the plurality of dummy channel structures D340 described with reference to FIG. 13. However, the plurality of dummy channel structures D440 arranged in the dummy channel area DA of the semiconductor device 400 include a second dummy channel structure group GY4 including second dummy channel structures that are arranged in a line in the second horizontal direction (the Y direction) across the bridge connection portion WLE3 of each of the plurality of gate lines 130.

The second dummy channel structures belonging to the second dummy channel structure group GY4, among the plurality of dummy channel structures D440, may include four offset dummy channel structures SD4 facing and adjacent to the bridge connection portion WLE3 in the second horizontal direction (the Y direction).

In a plan view, in each of the pair of main gate portions MGP, the second dummy channel structures belonging to the second dummy channel structure group GY4 may include two offset dummy channel structures SD4 and second normal dummy channel structures DN24, the second normal dummy channel structures DN24 being farther from the bridge connection portion WLE3 than the offset dummy channel structures SD4. In each of the pair of main gate portions MGP, an offset dummy channel structure SD4 and the second normal dummy channel structures DN24, which are arranged in a line in the second horizontal direction (the Y direction), may be arranged at regular pitches in the second horizontal direction (the Y direction). That is, in one main gate portion MGP, a center-to-center distance L42 of adjacent two out of the offset dummy channel structure SD4 and the second normal dummy channel structures DN24 may be constant.

A center-to-center distance L43 of two offset dummy channel structures SD4, which are included in the second dummy channel structure group GY4 and apart from each other with the bridge connection portion WLE3 therebetween in the second horizontal direction (the Y direction), may be greater than the center-to-center distance L42 of two normal dummy channel structures DN24 adjacent to each other in the second horizontal direction (the Y direction) from among the second normal dummy channel structures DN24.

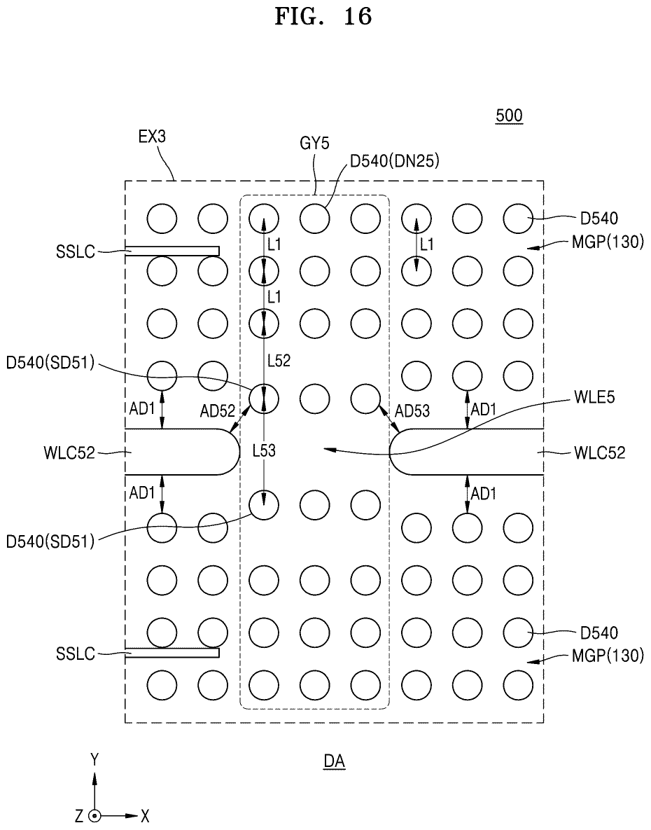

Referring to FIG. 16, the semiconductor device 500 has the same (or a substantially similar) configuration as the semiconductor device 100 described with reference to FIGS. 1 to 10. However, the semiconductor device 500 includes a local word line cut structure WLC52, which passes through respective local regions of the plurality of gate lines 130 in the vertical direction (the Z direction) and has a shape intermittently extending in the first horizontal direction (the X direction), and a plurality of dummy channel structures D540, which are arranged in the dummy channel area DA to pass through the plurality of gate lines 130 in the vertical direction (the Z direction). The plurality of gate lines 130 may each include a bridge connection portion WLE5 connecting a pair of main gate portions MGP to each other, and the bridge connection portion WLE5 may have a width defined in the first horizontal direction (the X direction) by the local word line cut structure WLC52. The local word line cut structure WLC52 and the plurality of dummy channel structures D540 have the same (or a substantially similar) configurations as the local word line cut structure WLC2 and the plurality of dummy channel structures D140 described with reference to FIGS. 5A to 10, respectively. However, the plurality of dummy channel structures D540 arranged in the dummy channel area DA of the semiconductor device 500 include a second dummy channel structure group GY5 including second dummy channel structures that are arranged in a line in the second horizontal direction (the Y direction) across the bridge connection portion WLE5 of each of the plurality of gate lines 130.

The second dummy channel structures belonging to the second dummy channel structure group GY5, among the plurality of dummy channel structures D540, may include six offset dummy channel structures SD51 facing and adjacent to the bridge connection portion WLE5 in the second horizontal direction (the Y direction).

In a plan view, in each of the pair of main gate portions MGP, the second dummy channel structures belonging to the second dummy channel structure group GY5 may include three offset dummy channel structures SD51 and second normal dummy channel structures DN25, the second normal dummy channel structures DN25 being farther from the bridge connection portion WLE5 than the three offset dummy channel structures SD51.

In each of the pair of main gate portions MGP, the minimum distance in the second horizontal direction (the Y direction) between an offset dummy channel structure SD51 and a second normal dummy channel structure DN25 closest to the offset dummy channel structure SD51 in the second horizontal direction (the Y direction) from among the second normal dummy channel structures DN25 may be greater than the minimum distance between two second normal dummy channel structures DN25 adjacent to each other in the second horizontal direction (the Y direction) from among the second normal dummy channel structures DN25. Therefore, in each of the pair of main gate portions MGP, a minimum distance L52 in the second horizontal direction (the Y direction) between the center of the offset dummy channel structure SD51 and the center of the second normal dummy channel structure DN25 closest to the offset dummy channel structure SD51 in the second horizontal direction (the Y direction) from among the second normal dummy channel structures DN25 may be greater than a minimum distance L1 between the centers of the two second normal dummy channel structures DN25 adjacent to each other in the second horizontal direction (the Y direction) from among the second normal dummy channel structures DN25.

The respective centers of two offset dummy channel structures SD51 arranged in a line in the second horizontal direction (the Y direction), among the six offset dummy channel structures SD51 belonging to the second dummy channel structure group GY5, may be arranged on a straight line extending in the second horizontal direction (the Y direction). A minimum distance L53 between the centers of the two offset dummy channel structures SD51 on the straight line in the second horizontal direction (the Y direction) may be equal to or greater than a minimum distance L52 between the center of the offset dummy channel structure SD51 and the center of the second normal dummy channel structure DN25 closest to the offset dummy channel structure SD51 in the second horizontal direction (the Y direction).

The respective centers of two offset dummy channel structures SD51 arranged in a line in the first horizontal direction (the X direction), among the six offset dummy channel structures SD51 belonging to the second dummy channel structure group GY5, may be arranged on a straight line extending in the first horizontal direction (the X direction).

The semiconductor device 500 has an offset minimum distance AD52 or AD53 between the offset dummy channel structure SD51 and the local word line cut structure WLC52. The semiconductor device 500 has a normal minimum distance AD1 between the local word line cut structure WLC52 and a dummy channel structure D540 facing and closest to the local word line cut structure WLC52 in the second horizontal direction (the Y direction). The offset minimum distance AD52 or AD53 may be selected from a range of ±0.5 nm from the normal minimum distance AD1.

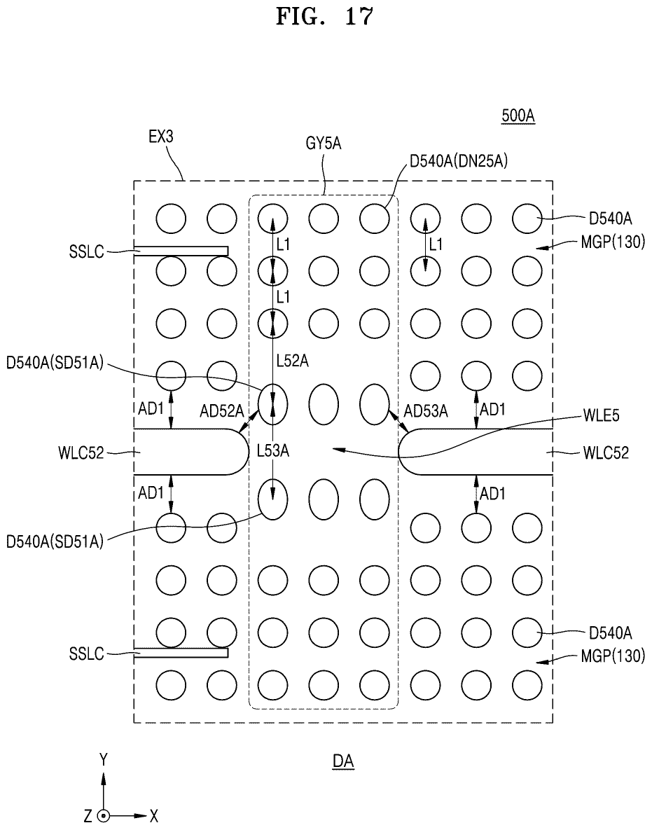

Referring to FIG. 17, the semiconductor device 500A has the same (or a substantially similar) configuration as the semiconductor device 500 described with reference to FIG. 16. However, the semiconductor device 500A includes a plurality of dummy channel structures D540A arranged in the dummy channel area DA.

The plurality of dummy channel structures D540A have the same (or a substantially similar) configuration as the plurality of dummy channel structures D540 described with reference to FIG. 16. However, the plurality of dummy channel structures D540A arranged in the dummy channel area DA of the semiconductor device 500A include a second dummy channel structure group GY5A including second dummy channel structures that are arranged in a line in the second horizontal direction (the Y direction) across the bridge connection portion WLE5 of each of the plurality of gate lines 130.

The second dummy channel structures belonging to the second dummy channel structure group GY5A, among the plurality of dummy channel structures D540A, may include six offset dummy channel structures SD51A facing and adjacent to the bridge connection portion WLE5 in the second horizontal direction (the Y direction).

In a plan view, in each of the pair of main gate portions MGP, the second dummy channel structures belonging to the second dummy channel structure group GY5A may include three offset dummy channel structures SD51A and second normal dummy channel structures DN25A, the second normal dummy channel structures DN25A being farther from the bridge connection portion WLE5 than the three offset dummy channel structures SD51A.

In a plan view, an offset dummy channel structure SD51A may have a shape in which the size thereof in the second horizontal direction (the Y direction) is greater than the size thereof in the first horizontal direction (the X direction). In some embodiments, the offset dummy channel structure SD51A may have an elliptical planar shape. In a plan view, the size, in the second horizontal direction (the Y direction), of each of the six offset dummy channel structures SD51A belonging to the second dummy channel structure group GY5A may be greater than the size, in the second horizontal direction (the Y direction), of each of the second normal dummy channel structures DN25A.

The minimum distance in the second horizontal direction (the Y direction) between the offset dummy channel structure SD51A and a second normal dummy channel structure DN25A closest to the offset dummy channel structure SD51A in the second horizontal direction (the Y direction) from among the second normal dummy channel structures DN25A may be greater than the minimum distance between two second normal dummy channel structures DN25A adjacent to each other in the second horizontal direction (the Y direction) from among the second normal dummy channel structures DN25A. Therefore, a minimum distance L52A in the second horizontal direction (the Y direction) between the center of the offset dummy channel structure SD51A and the center of the second normal dummy channel structure DN25A closest to the offset dummy channel structure SD51A in the second horizontal direction (the Y direction) from among the second normal dummy channel structures DN25A may be greater than a minimum distance L1 between the centers of two second normal dummy channel structures DN25A adjacent to each other in the second horizontal direction (the Y direction) from among the second normal dummy channel structures DN25A.

The semiconductor device 500A has an offset minimum distance AD52A or AD53A between the offset dummy channel structure SD51A and the local word line cut structure WLC52. The semiconductor device 500A has a normal minimum distance AD1 between the local word line cut structure WLC52 and a dummy channel structure D540A facing and closest to the local word line cut structure WLC52 in the second horizontal direction (the Y direction). The offset minimum distance AD52A or AD53A may be selected from a range of +0.5 nm from the normal minimum distance AD1.

The respective centers of two offset dummy channel structures SD51A arranged in a line in the second horizontal direction (the Y direction), among the six offset dummy channel structures SD51A belonging to the second dummy channel structure group GY5A, may be arranged on a straight line extending in the second horizontal direction (the Y direction). A minimum distance L53A between the centers of the two offset dummy channel structures SD51A on the straight line in the second horizontal direction (the Y direction) may be equal to or greater than a minimum distance L52A between the center of the offset dummy channel structure SD51A and the center of the second normal dummy channel structure DN25A closest to the offset dummy channel structure SD51A in the second horizontal direction (the Y direction).

The respective centers of two offset dummy channel structures SD51A arranged in a line in the first horizontal direction (the X direction), among the six offset dummy channel structures SD51A belonging to the second dummy channel structure group GY5A, may be arranged on a straight line extending in the first horizontal direction (the X direction).

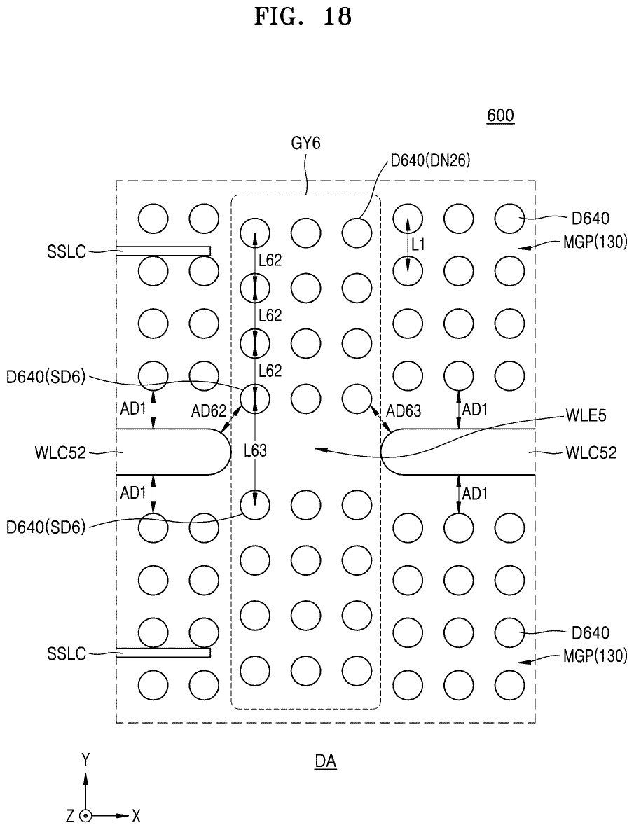

Referring to FIG. 18, the semiconductor device 600 has the same (or a substantially similar) configuration as the semiconductor device 500 described with reference to FIG. 16. However, the semiconductor device 600 includes a plurality of dummy channel structures D640 arranged in the dummy channel area DA.

The plurality of dummy channel structures D640 have the same (or a substantially similar) configuration as the plurality of dummy channel structures D540 described with reference to FIG. 16. However, the plurality of dummy channel structures D640 arranged in the dummy channel area DA of the semiconductor device 600 include a second dummy channel structure group GY6 including second dummy channel structures that are arranged in a line in the second horizontal direction (the Y direction) across the bridge connection portion WLE5 of each of the plurality of gate lines 130.

The second dummy channel structures belonging to the second dummy channel structure group GY6, among the plurality of dummy channel structures D640, may include six offset dummy channel structures SD6 facing and adjacent to the bridge connection portion WLE5 in the second horizontal direction (the Y direction).

In a plan view, in each of the pair of main gate portions MGP, the second dummy channel structures belonging to the second dummy channel structure group GY6 may include three offset dummy channel structures SD6 and second normal dummy channel structures DN26, the second normal dummy channel structures DN26 being farther from the bridge connection portion WLE5 than the offset dummy channel structures SD6. In each of the pair of main gate portions MGP, an offset dummy channel structure SD6 and the second normal dummy channel structures DN26, which are arranged in a line in the second horizontal direction (the Y direction), may be arranged at regular pitches in the second horizontal direction (the Y direction). That is, in one main gate portion MGP, a center-to-center distance L62 of adjacent two out of the offset dummy channel structure SD6 and the second normal dummy channel structures DN26 may be constant.

A center-to-center distance L63 of two offset dummy channel structures SD6, which are included in the second dummy channel structure group GY6 and apart from each other with the bridge connection portion WLE5 therebetween in the second horizontal direction (the Y direction), may be greater than the center-to-center distance L62 of two normal dummy channel structures DN26 adjacent to each other in the second horizontal direction (the Y direction) from among the second normal dummy channel structures DN26.

According to the semiconductor devices 100A, 200, 300, 300A, 400, 500, 500A, and 600 described with reference to FIGS. 11 to 18, similar to the semiconductor device 100 described with reference to FIGS. 1 to 10, even when the planar area of the bridge connection portion WLE, WLE3, or WLE5 of each of the plurality of gate lines 130 is relatively large, the bridge connection portion WLE, WLE3, or WLE5 of each of the plurality of gate lines 130, and local regions overlapping the bridge connection portion WLE, WLE3, or WLE5 in the vertical direction (the Z direction), in each of the plurality of first insulating films 132, may be stably supported by the offset dummy channel structure SD1A, SD2, SD31, SD31A, SD4, SD51, SD51A, or SD52. In addition, during the process of fabricating each of the semiconductor devices 100A, 200, 300, 300A, 400, 500, 500A, and 600, before the plurality of gate lines 130 are formed, structural defects, such as a pattern collapse phenomenon in which the local regions overlapping a region corresponding to the bridge connection portion WLE, WLE3, or WLE5, in each of the plurality of first insulating films 132, collapse, may be mitigated and/or prevented, and thus, the reliability and electrical characteristics of each of the semiconductor devices 100A, 200, 300, 300A, 400, 500, 500A, and 600 may improve.

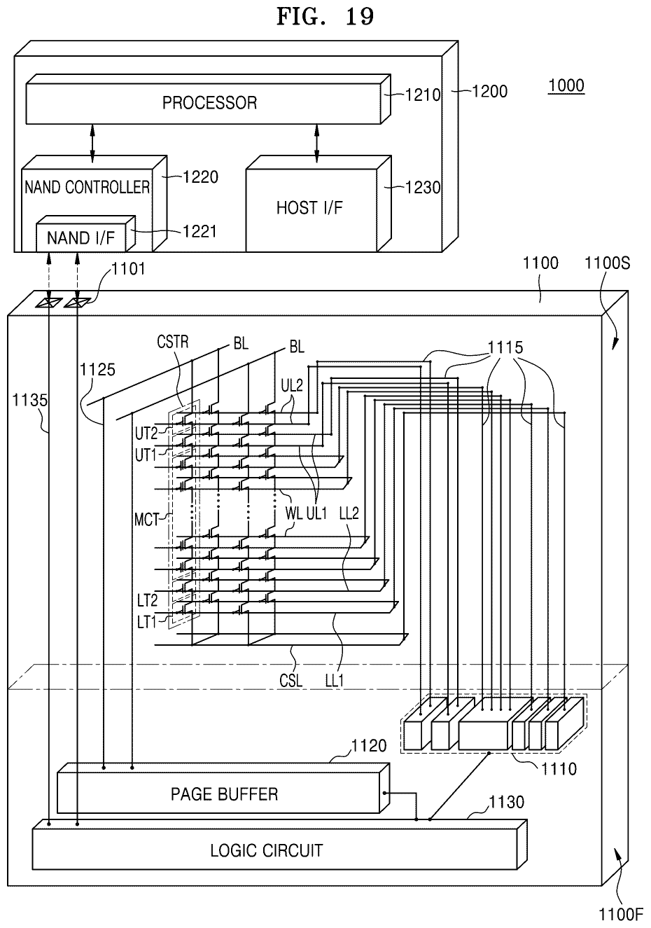

FIG. 19 is a diagram schematically illustrating an electronic system including a semiconductor device according to some embodiments.

Referring to FIG. 19, an electronic system 1000 according to some embodiment may include a semiconductor device 1100 and a controller 1200 electrically connected to the semiconductor device 1100. The electronic system 1000 may include a storage device including one or more semiconductor devices 1100 or an electronic device including a storage device. For example, the electronic system 1000 may include a solid-state drive (SSD) device, a universal serial bus (USB), a computing system, a medical device, or a communication device, which includes at least one semiconductor device 1100.

The semiconductor device 1100 may include a nonvolatile memory device. For example, the semiconductor device 1100 may include a NAND flash memory device including at least one of the structures of the semiconductor devices 100, 100A, 200, 300, 300A, 400, 500, 500A, and 600 described with reference to FIGS. 1 to 18. The semiconductor device 1100 may include a first structure 1100F and a second structure 1100S on the first structure 1100F. In some embodiments, the first structure 1100F may be arranged beside the second structure 1100S. The first structure 1100F may include a peripheral circuit structure, which includes a decoder circuit 1110, a page buffer 1120, and a logic circuit 1130. The second structure 1100S may include a memory cell structure, which includes a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL. The first structure 1100F and the second structure 1100S may, for example, correspond to the peripheral circuit 30 and the memory cell array 20 of FIG. 1, respectively.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The respective numbers of lower transistors LT1 and LT2 and upper transistors UT1 and UT2 may be variously modified depending on embodiments.

In some embodiments, the upper transistors UT1 and UT2 may include a string select transistor and the lower transistors LT1 and LT2 may include a ground select transistor. A plurality of gate lower lines (that is, LL1 and LL2) may be gate electrodes of the lower transistors LT1 and LT2, respectively. A word line WL may be a gate electrode of a memory cell transistor MCT, and a plurality of gate upper lines (that is, UL1 and UL2) may be gate electrodes of the upper transistors UT1 and UT2, respectively.

The common source line CSL, the plurality of gate lower lines (that is, LL1 and LL2), the plurality of word lines WL, and the plurality of gate upper lines (that is, UL1 and UL2) may be electrically connected to the decoder circuit 1110 via a plurality of first connection wiring lines 1115 extending from inside the first structure 1100F to the second structure 1100S. A plurality of bit lines BL may be electrically connected to the page buffer 1120 via a plurality of second connection wiring lines 1125 extending from inside the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 via an input/output pad 1101 electrically connected to the logic circuit 1130. The input/output pad 1101 may be electrically connected to the logic circuit 1130 via an input/output connection wiring line 1135 extending from inside the first structure 1100F to the second structure 1100S.

The controller 1200 may include a processor 1210, a NAND controller 1220, and a host interface 1230. Depending on embodiments, the electronic system 1000 may include a plurality of semiconductor devices 1100, and in this case, the controller 1200 may control the plurality of semiconductor devices 1100.

The processor 1210 may control all operations of the electronic system 1000 including the controller 1200. The processor 1210 may be operated by certain firmware and may access the semiconductor device 1100 by controlling the NAND controller 1220. The NAND controller 1220 may include a NAND interface 1221 that processes communication with the semiconductor device 1100. A control command for controlling the semiconductor device 1100, data to be written to the plurality of memory cell transistors MCT of the semiconductor device 1100, data to be read from the plurality of memory cell transistors MCT of the semiconductor device 1100, and the like may be transmitted via the NAND interface 1221. The host interface 1230 may provide a function of communication between the electronic system 1000 and an external host. When a control command is received from the external host via the host interface 1230, the processor 1210 may control the semiconductor device 1100 in response to the control command.

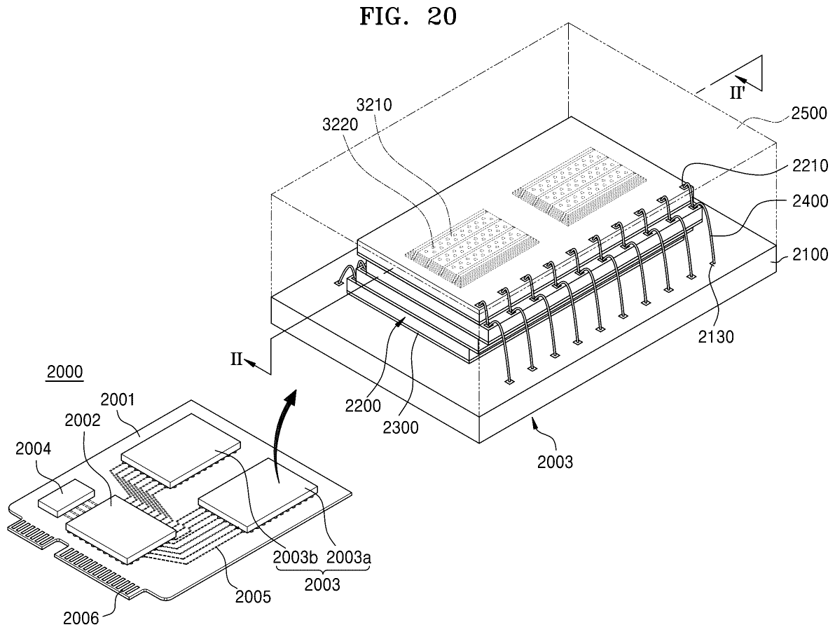

FIG. 20 is a perspective view schematically illustrating an electronic system including a semiconductor device according to embodiments.

Referring to FIG. 20, an electronic system 2000 according to some embodiment may include a main substrate 2001, and a controller 2002, one or more semiconductor packages 2003, and DRAM 2004, which are mounted on the main substrate 2001. The semiconductor packages 2003 and the DRAM 2004 may be connected to the controller 2002 by a plurality of wiring patterns 2005 formed on the main substrate 2001. The semiconductor packages 2003 may be and/or include data storage spaces.

The main substrate 2001 may include a connector 2006 including a plurality of pins to be coupled with an external host. The number of pins and the arrangement of the plurality of pins, in the connector 2006, may vary depending on a communication interface between the electronic system 2000 and the external host. In some embodiments, the electronic system 2000 may communicate with the external host according an interface, such as Universal Serial Bus (USB), Peripheral Component Interconnect Express (PCI-Express), Serial Advanced Technology Attachment (SATA), and M-Phy for Universal Flash Storage (UFS). In some embodiments, the electronic system 2000 may be operated by power supplied from the external host via the connector 2006. The electronic system 2000 may further include a power management integrated circuit (PMIC) distributing the power, which is supplied from the external host to the controller 2002 and the semiconductor packages 2003.

The controller 2002 may be configured to write data to or read data from the semiconductor packages 2003 and may improve an operation speed of the electronic system 2000.

The DRAM 2004 may be a buffer memory configured to alleviate a speed difference between the external host and the semiconductor packages 2003. For example, the DRAM 2004 in the electronic system 2000 may operate as a kind of cache memory and may provide a space for temporarily storing data in a control operation on the semiconductor packages 2003. When the DRAM 2004 is included in the electronic system 2000, the controller 2002 may further include a DRAM controller for controlling the DRAM 2004 in addition to a NAND controller for controlling the semiconductor packages 2003.

The semiconductor packages 2003 may include first and second semiconductor packages 2003a and 2003b, which are apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, a bonding layer 2300 on a lower surface of each of the plurality of semiconductor chips 2200, a connection structure 2400 electrically connecting the plurality of semiconductor chips 2200 to the package substrate 2100, and a molding layer 2500 arranged on the package substrate 2100 to cover the plurality of semiconductor chips 2200 and the connection structure 2400.

The package substrate 2100 may include a printed circuit board including a plurality of package upper pads 2130. Each of the plurality of semiconductor chips 2200 may include an input/output pad 2210. The input/output pad 2210 may correspond to the input/output pad 1101 of FIG. 19. Each of the plurality of semiconductor chips 2200 may include a plurality of gate stacks 3210 and a plurality of channel structures 3220. Each of the plurality of semiconductor chips 2200 may include at least one of the structures of the semiconductor devices 100, 100A, 200, 300, 300A, 400, 500, 500A, and 600 described with reference to FIGS. 1 to 18.

In some embodiments, the connection structure 2400 may include a bonding wire electrically connecting the input/output pad 2210 and a package upper pad 2130 to each other. Therefore, in the first and second semiconductor packages 2003a and 2003b, the plurality of semiconductor chips 2200 may be electrically connected to each other in a bonding wire manner and may be electrically connected to the package upper pads 2130 of the package substrate 2100. In some embodiments, in the first and second semiconductor packages 2003a and 2003b, the plurality of semiconductor chips 2200 may be electrically connected to each other by a connection structure including a through-silicon via (TSV) rather than by the connection structure 2400 of a bonding wire type.

In some embodiments, the controller 2002 and the plurality of semiconductor chips 2200 may be included in one package. In some embodiments, the controller 2002 and the plurality of semiconductor chips 2200 may be mounted on a separate interposer substrate, which is different from the main substrate 2001, and may be connected to each other by wiring lines formed on the interposer substrate.

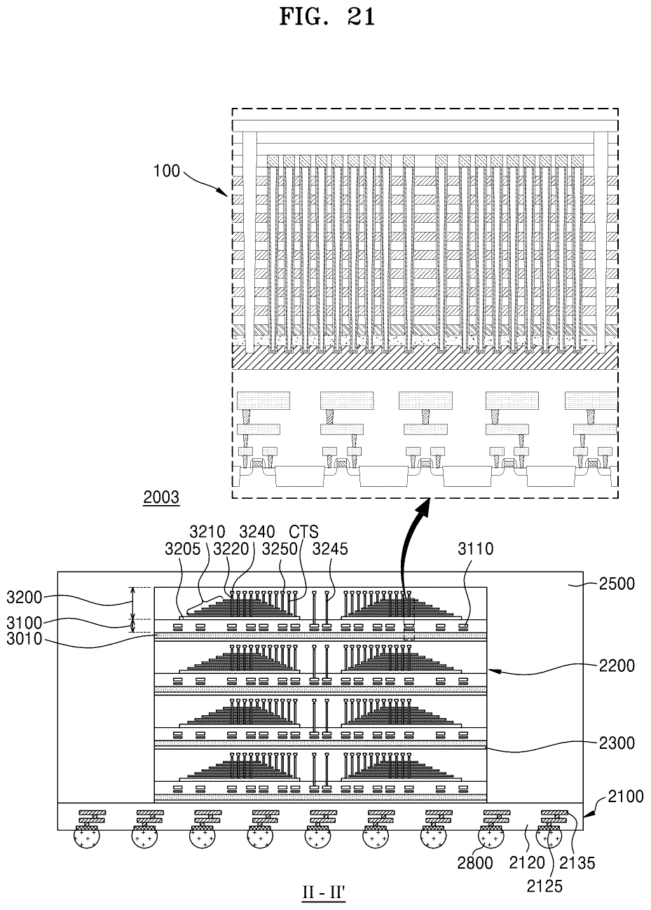

FIG. 21 is a cross-sectional view schematically illustrating semiconductor packages according to some embodiments. FIG. 21 illustrates a more detailed configuration of the semiconductor packages 2003 of FIG. 20 according to the cross-section taken along a line II-II′ of FIG. 20.

Referring to FIG. 21, in the semiconductor package 2003, the package substrate 2100 may include a printed circuit board. The package substrate 2100 may include a package substrate body 2120, a plurality of package upper pads 2130 (see FIG. 20) arranged on an upper surface of the package substrate body 2120, a plurality of lower pads 2125 arranged on or exposed by a lower surface of the package substrate body 2120, and a plurality of inner wiring lines 2135 arranged inside the package substrate body 2120 to electrically connect the plurality of package upper pads 2130 to the plurality of lower pads 2125. The plurality of package upper pads 2130 may be electrically connected to a plurality of connection structures 2400, respectively. The plurality of lower pads 2125 may be connected to the plurality of wiring patterns 2005 on the main substrate 2001 of the electronic system 2000 shown in FIG. 20 via a plurality of conductive connection units 2800, respectively.

Each of the plurality of semiconductor chips 2200 may include a semiconductor substrate 3010, and a first structure 3100 and a second structure 3200 stacked in the stated order on the semiconductor substrate 3010. The first structure 3100 may include a peripheral circuit area including a plurality of peripheral wiring lines 3110. The second structure 3200 may include a common source line 3205, a gate stack 3210 on the common source line 3205, a channel structure 3220 passing through the gate stack 3210, a bit line 3240 electrically connected to the channel structure 3220, and a gate connection wiring line 3250 electrically connected to a word line (that is, WL of FIG. 13) of the gate stack 3210 via a contact CTS. As noted above, each of the plurality of semiconductor chips 2200 may include at least one of the structures of the semiconductor devices 100, 100A, 200, 300, 300A, 400, 500, 500A, and 600 described with reference to FIGS. 1 to 18.

Each of the plurality of semiconductor chips 2200 may include a through-wiring line 3245 electrically connected to the plurality of peripheral wiring lines 3110 of the first structure 3100 and extending to the inside of the second structure 3200. The through-wiring line 3245 may be arranged outside the gate stack 3210. In some embodiments, the semiconductor package 2003 may further include a through-wiring line passing through the gate stack 3210. Each of the plurality of semiconductor chips 2200 may further include an input/output pad (that is, 2210 of FIG. 20) electrically connected to the plurality of peripheral wiring lines 3110 of the first structure 3100.

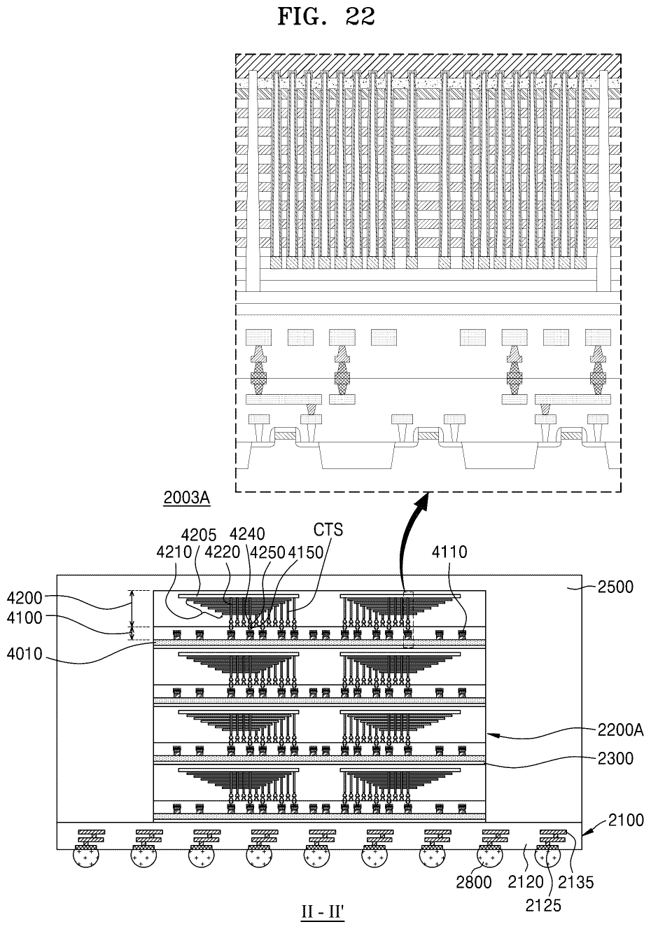

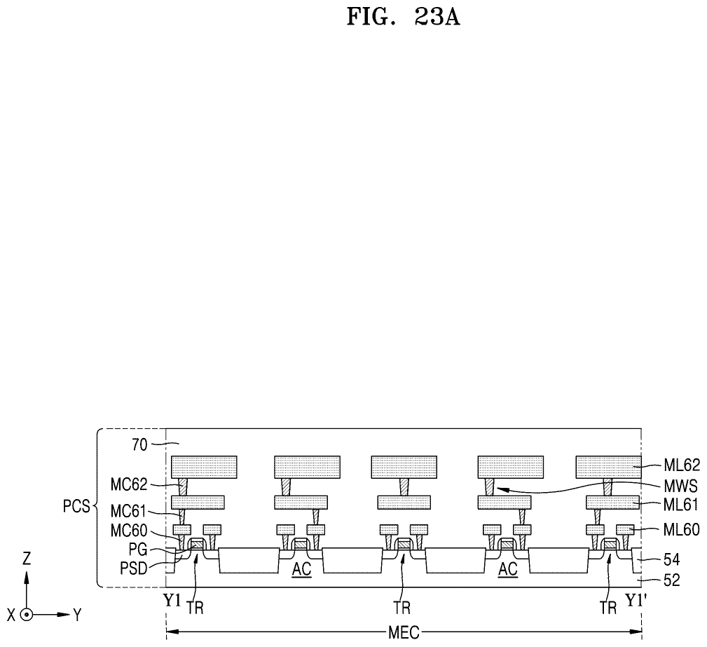

FIG. 22 is a cross-sectional view schematically illustrating semiconductor packages according to some embodiments. FIG. 22 illustrates a cross-sectional configuration of a portion of a semiconductor package 2003A, which corresponds to the cross-section taken along the line II-II′ of FIG. 20. In FIG. 22, the same reference numerals as in FIG. 21 respectively denote the same members, and thereby the differences thereto are discussed, while repeated descriptions thereof may be omitted for brevity.

Referring to FIG. 22, in the semiconductor package 2003A, semiconductor chips 2200A may each include a semiconductor substrate 4010, a first structure 4100 on the semiconductor substrate 4010, and a second structure 4200 arranged on the first structure 4100 and bonded to the first structure 4100 in a wafer bonding manner.

The first structure 4100 may include a peripheral circuit area including a peripheral wiring line 4110 and first bonding structures 4150. The second structure 4200 may include a common source line 4205, a gate stack structure 4210 between the common source line 4205 and the first structure 4100, memory channel structures 4220 and an isolation structure 4230 each passing through the gate stack structure 4210, and second bonding structures 4250 respectively and electrically connected to the memory channel structures 4220 and word lines (that is, WL of FIG. 19) of the gate stack structure 4210. For example, the second bonding structures 4250 may be respectively and electrically connected to the memory channel structures 4220 and the word lines (that is, WL of FIG. 19) via bit lines 4240 electrically connected to the memory channel structures 4220 and via gate connection wiring lines electrically connected to the word lines (that is, WL of FIG. 1). The first bonding structures 4150 of the first structure 4100 may be brought into contact with and bonded to the second bonding structures 4250 of the second structure 4200, respectively. Bonded portions of the first bonding structures 4150 and the second bonding structures 4250 may include, for example, copper (Cu).

The second structure 4200 may include at least one of the semiconductor devices 100, 100A, 200, 300, 300A, 400, 500, 500A, and 600 described with reference to FIGS. 1 to 18.

Next, a method of fabricating a semiconductor device, according to some embodiments, is described in detail.

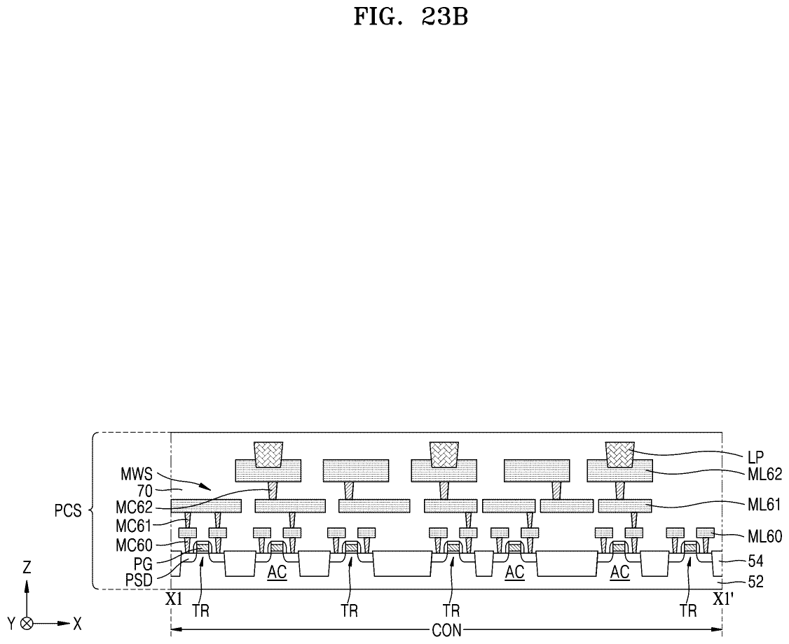

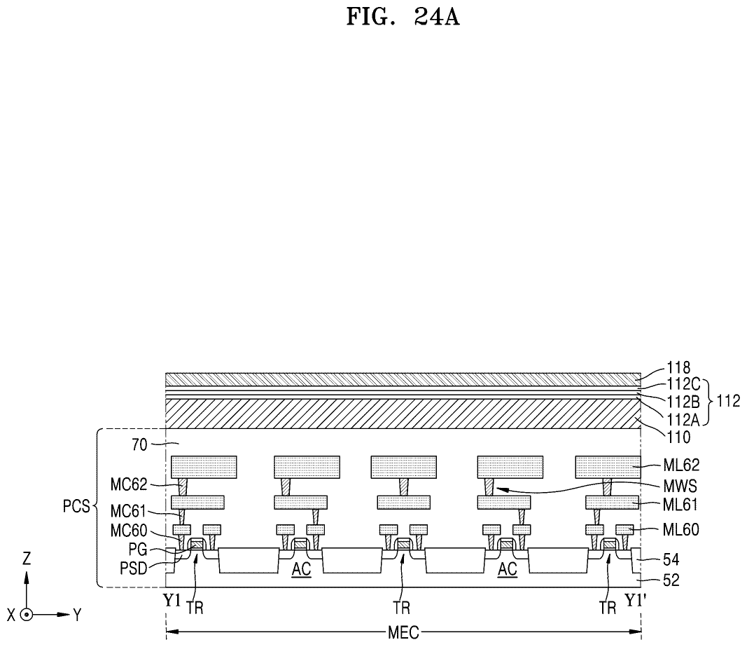

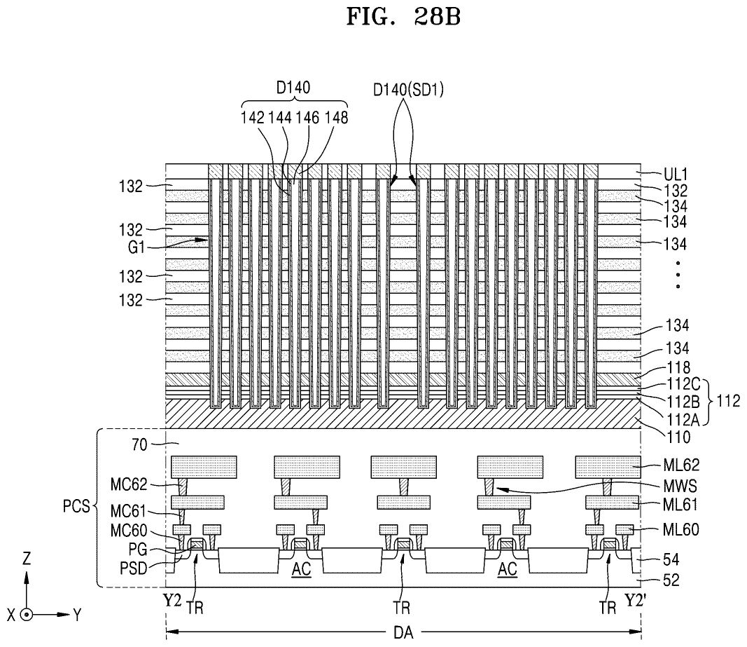

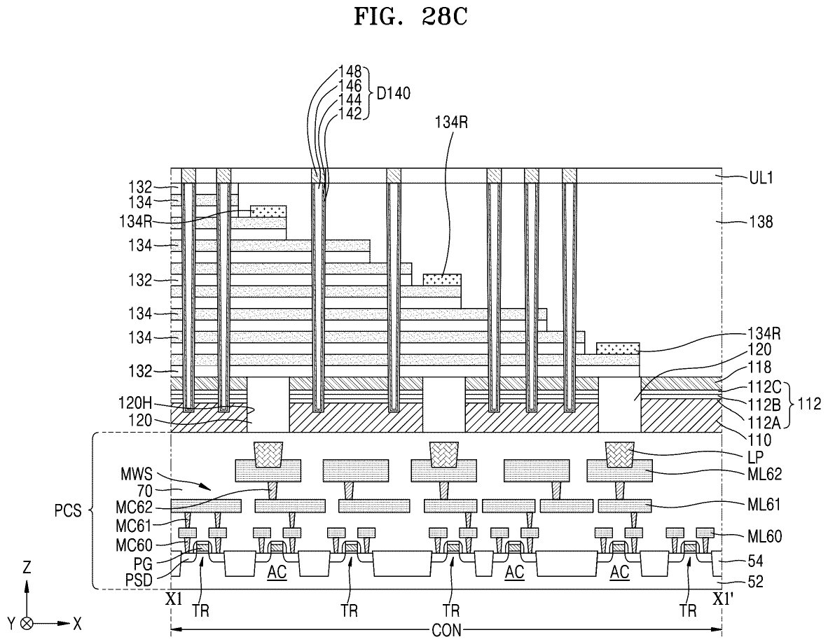

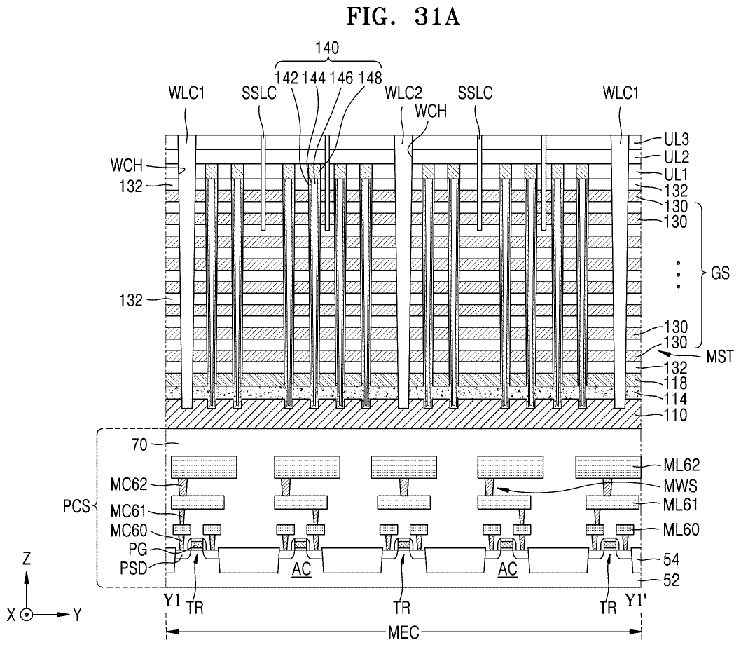

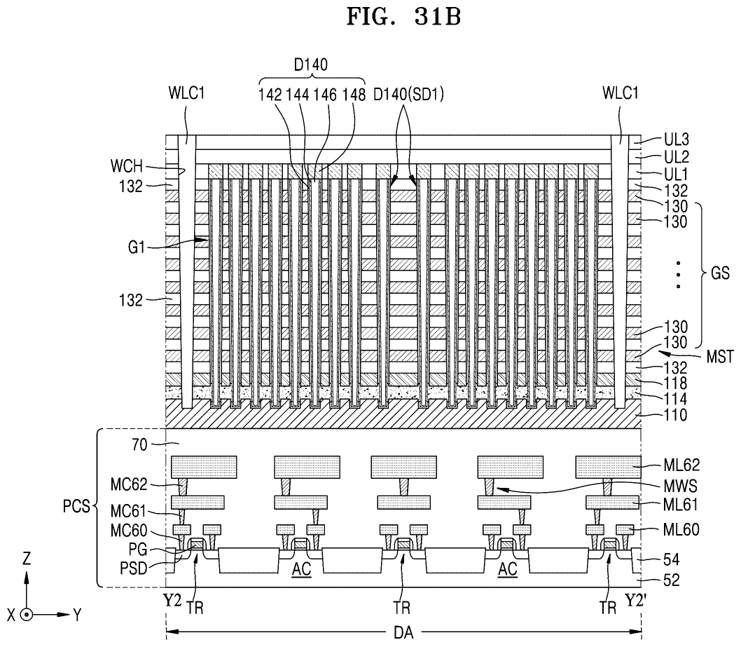

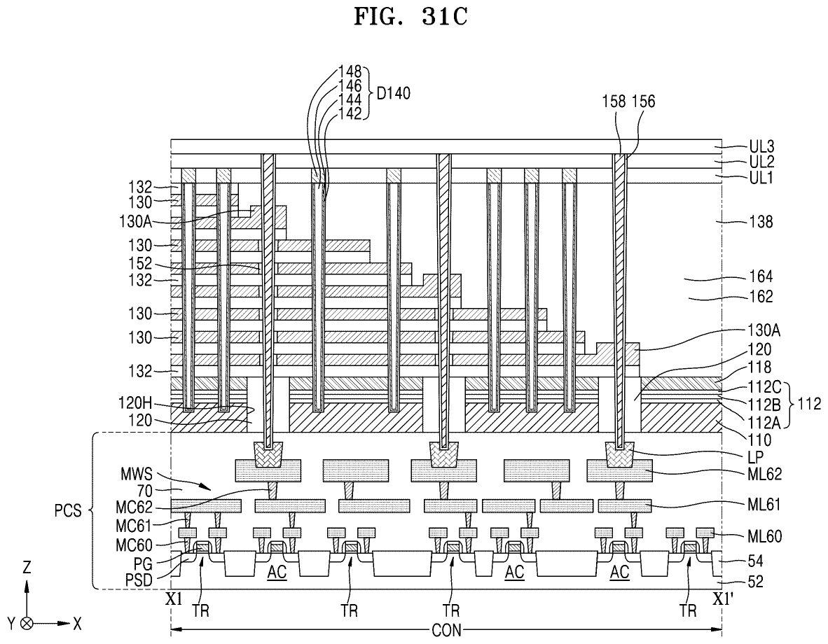

FIGS. 23A to 34 are cross-sectional views illustrating a method of fabricating a semiconductor device according to some embodiments. More specifically, FIGS. 23A, 24A, 25A, 28A, and 31A are cross-sectional views each illustrating some components in a region corresponding to the cross-section taken along the line Y1-Y1′ of FIG. 5A, according to a sequence of processes, FIGS. 28B and 31B are cross-sectional views each illustrating some components in a region corresponding to the cross-section taken along the line Y2-Y2′ of FIG. 5A, according to the sequence of processes, and FIGS. 23B, 24B, 25B, 26, 27, 28C, 29, 30, 31C, 32, 33, and 34 are cross-sectional views each illustrating some components in a region corresponding to the cross-section taken along the line X1-X1′ of FIG. 6, according to the sequence of processes. An example of a method of fabricating the semiconductor device 100 described with reference to FIGS. 1 to 10 is described with reference to FIGS. 23A to 34. In FIGS. 23A to 34, the same reference numerals as in FIGS. 1 to 10 respectively denote the same members, and thereby the differences thereto are discussed, while repeated descriptions thereof may be omitted for brevity.

Referring to FIGS. 23A and 23B, a peripheral circuit structure PCS including a substrate 52, a plurality of transistors TR, a multilayer wiring structure MWS, a plurality of conductive landing pads LP, and an interlayer dielectric 70 may be formed. Each of the plurality of conductive landing pads LP may be arranged to correspond to a position at which a memory cell contact MCC or a through-electrode THV (see FIG. 9) is arranged. The interlayer dielectric 70 may be formed to cover a plurality of wiring layers ML62 at the uppermost position from among a plurality of wiring layers ML60, ML61, and ML62.

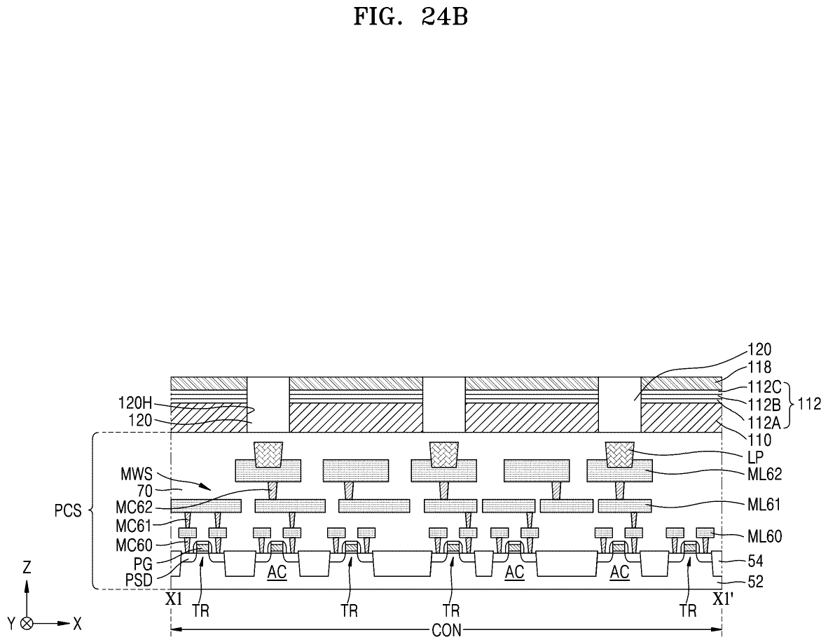

Referring to FIGS. 24A and 24B, a plate common source line 110 may be formed on the resulting product of FIGS. 23A and 23B, and an insulating plate 112 and a second conductive plate 118 may be formed in the stated order to cover the plate common source line 110. The insulating plate 112 may include a multilayer-structured insulating film including a first insulating thin film 112A, a second insulating thin film 112B, and a third insulating thin film 112C.

Next, as shown in FIG. 24B, a plurality of through-openings 120H may be formed in a portion of the connection area CON to pass through the plate common source line 110, the insulating plate 112, and the second conductive plate 118, and a plurality of insulating plugs 120 may be formed to respectively fill the plurality of through-openings 120H.

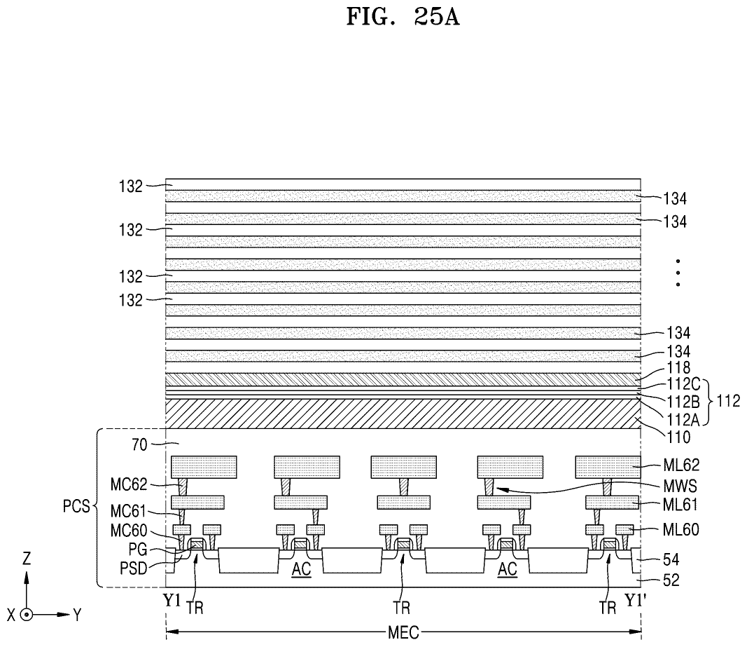

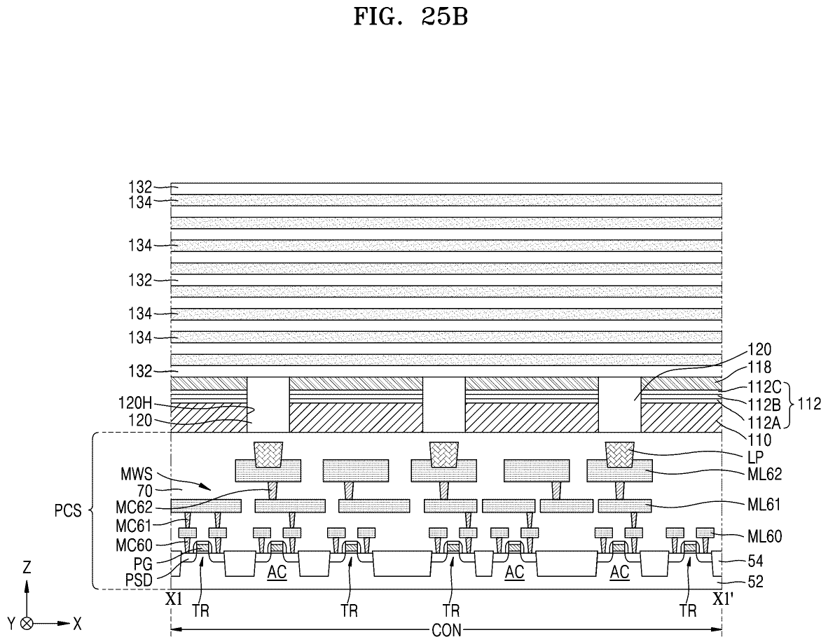

Referring to FIGS. 25A and 25B, in the memory cell area MEC and the connection area CON, a plurality of first insulating films 132 and a plurality of second insulating films 134 may be alternately stacked one-by-one on the second conductive plate 118 and the insulating plugs 120. In at least one embodiment, the plurality of first insulating films 132 may each include a silicon oxide film, and the plurality of second insulating films 134 may each include a silicon nitride film. Some of the plurality of second insulating films 134 may function to secure spaces for forming the plurality of gate lines 130 shown in FIGS. 7, 8, and 9 in a subsequent process.

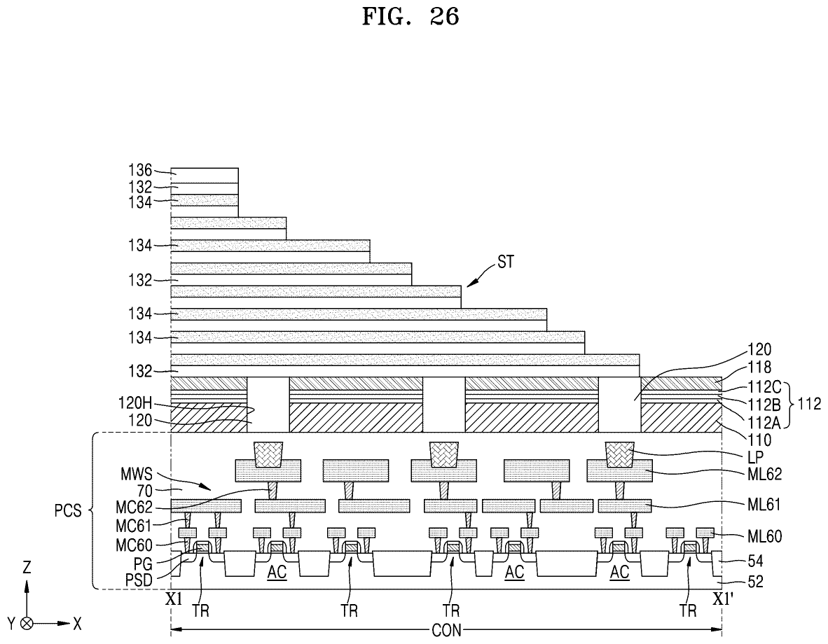

Referring to FIG. 26, in the resulting product having undergone the processes described with reference to FIGS. 25A and 25B, an etch stop film 136 may be formed to cover the uppermost first insulating film 132 from among the plurality of first insulating films 132, followed by removing a portion of each of the plurality of first insulating films 132 and the plurality of second insulating films 134 in the connection area CON by, e.g., a photolithography process, thereby forming a stepped structure ST in which an end portion of each of the plurality of first insulating films 132 and the plurality of second insulating films 134 has a gradually decreasing width in the horizontal direction away from the plate common source line 110.

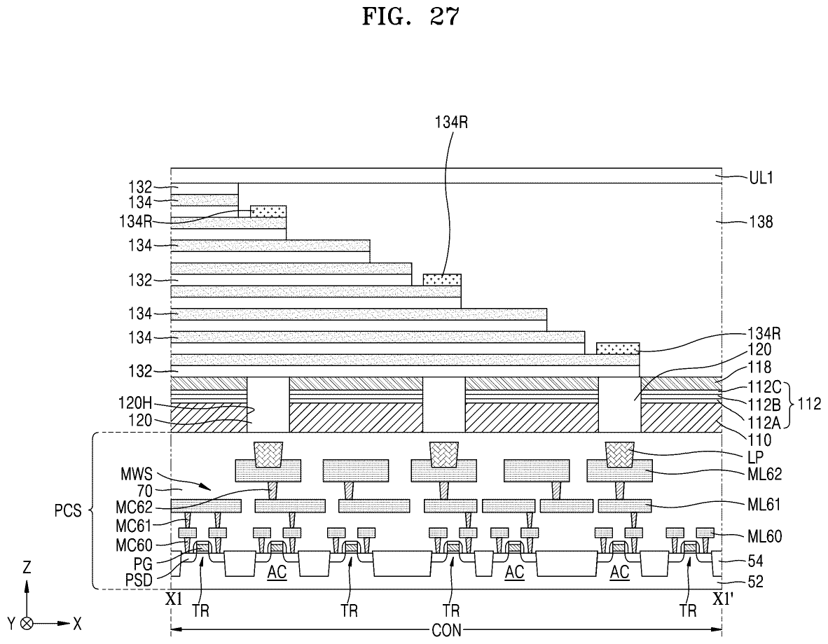

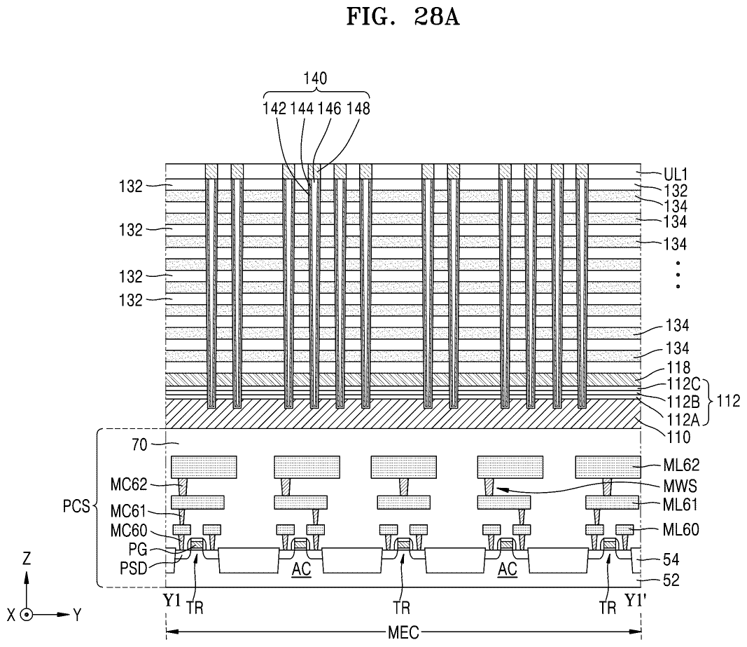

Referring to FIG. 27, in the resulting product having undergone the process described with FIG. 26, a third insulating film 134R may be formed on the end portion of each of the plurality of second insulating films 134 constituting the stepped structure ST. The third insulating film 134R may include, e.g., a silicon nitride film.

Although FIG. 27 illustrates third insulating films 134R respectively formed on end portions of some second insulating films 134 from among the plurality of second insulating films 134, a second insulating film 134 shown in FIG. 27 as not being covered by the third insulating film 134R, among the plurality of second insulating films 134, may have another portion not shown in FIG. 27 but covered by the third insulating film 134R.

In some embodiments, to form the third insulating film 134R on the end portion of each of the plurality of second insulating films 134, a preliminary third insulating film may be formed to cover the entire surface of the resulting product having undergone the process described with FIG. 26, and then, portions of the preliminary third insulating film may be removed. To form the third insulating film 134R, an atomic layer deposition (ALD) process or a plasma-enhanced chemical vapor deposition (PECVD) process may be used.

An interlayer dielectric 138 may be formed to cover the resulting product in which the third insulating film 134R is formed on the end portion of each of the plurality of second insulating films 134, as described above. During the formation of the interlayer dielectric 138, the etch stop film 136 may be removed by performing a chemical mechanical polishing (CMP) process for planarizing the upper surface of the interlayer dielectric 138, and as a result, the uppermost first insulating film 132 from among the plurality of first insulating films 132 may be exposed around the interlayer dielectric 138. Next, a first upper insulating film UL1 may be formed to cover the upper surface of each of the uppermost first insulating film 132 and the interlayer dielectric 138.

Referring to FIGS. 28A, 28B, and 28C, a plurality of channel structures 140, which extend lengthwise in the vertical direction (the Z direction) through the first upper insulating film UL1, the plurality of first insulating films 132, and the plurality of second insulating films 134 in the memory cell area MEC, and a plurality of dummy channel structures D140, which extend lengthwise in the vertical direction (the Z direction) through the first upper insulating film UL1, the plurality of first insulating films 132, the plurality of second insulating films 134, and the interlayer dielectric 138 in the dummy channel area DA and the connection area CON, may be formed. In the dummy channel area DA shown in FIG. 28B, the plurality of dummy channel structures D140 may be formed in the arrangement structure described with reference to FIGS. 5A, 5B, and 10.

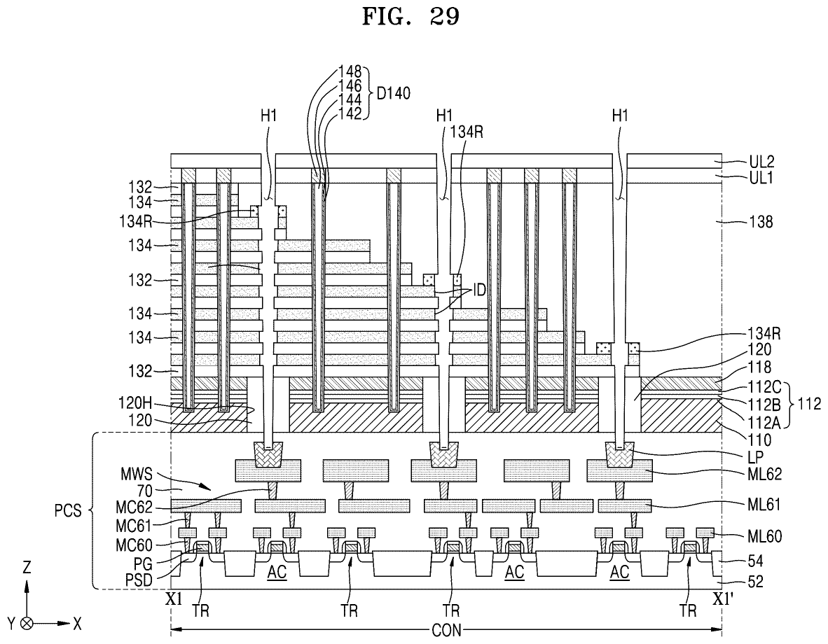

Referring to FIG. 29, a second upper insulating film UL2 may be formed on the resulting product having undergone the processes described with reference to FIGS. 28A, 28B, and 28C, and then, a plurality of vertical holes H1 may be formed in the connection area CON of the memory cell block BLK. A conductive landing pad LP of the peripheral circuit structure PCS may be exposed at the lower surface of each of the plurality of vertical holes H1.

Each of the plurality of vertical holes H1 may pass through, in the vertical direction (the Z direction), the second upper insulating film UL2, the first upper insulating film UL1, the interlayer dielectric 138, one of the third insulating films 134R, the plurality of second insulating films 134, the plurality of first insulating films 132, the insulating plug 120, and a portion of the interlayer dielectric 70 of the peripheral circuit structure PCS.

Next, the horizontal-direction width of each of the plurality of vertical holes H1 may be expanded by etching respective portions of the second insulating film 134 and the third insulating film 134R, which are exposed in each of the plurality of vertical holes H1, thereby forming a plurality of indent spaces ID. In some indent spaces ID from among the plurality of indent spaces ID, only the second insulating film 134 out of the second insulating film 134 and the third insulating film 134R may be exposed, and in some other indent spaces ID from among the plurality of indent spaces ID, both the second insulating film 134 and the third insulating film 134R may be exposed together.

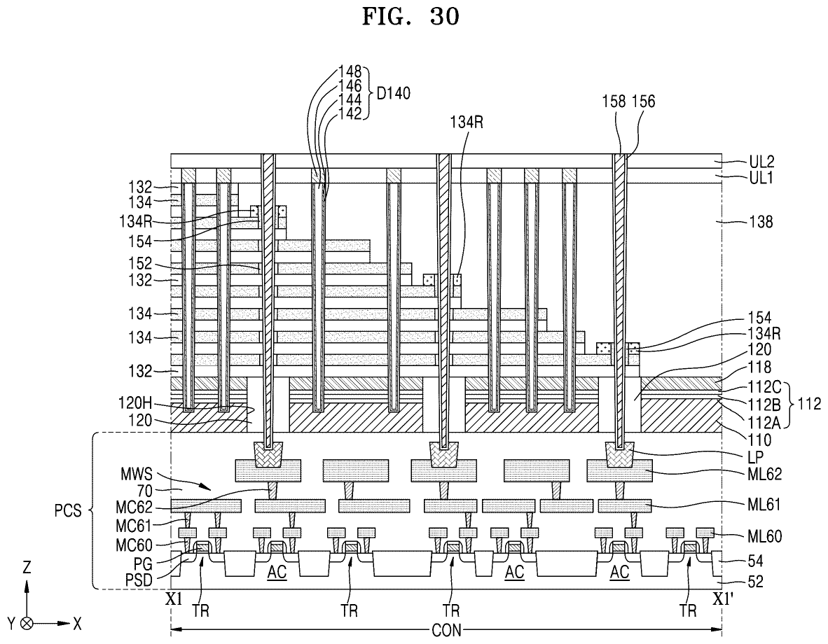

Referring to FIG. 30, after the processes described with reference to FIG. 29 are performed, among the plurality of indent spaces ID connected to each of the plurality of vertical holes H1 in the connection area CON of the memory cell block, an indent space ID exposing the second insulating film 134 may be filled with an insulating ring 152, and an indent space ID exposing both the second insulating film 134 and the third insulating film 134R may be filled with a sacrificial insulating ring 154. The insulating ring 152 may include a silicon oxide film. The sacrificial insulating ring 154 may include the same (or substantially similar) material as the second insulating film 134. For example, the sacrificial insulating ring 154 may include, e.g., a silicon nitride film.

In some embodiments, a process may be performed such that the insulating ring 152 is formed first in the indent space ID exposing the second insulating film 134 in each of the plurality of vertical holes H1, followed by forming the sacrificial insulating ring 154 in the indent space ID exposing both the second insulating film 134 and the third insulating film 134R in each of the plurality of vertical holes H1. In some embodiments, an etch stop insulating liner (not shown) may be arranged between the second insulating film 134 and the insulating ring 152. The etch stop insulating liner may include a silicon nitride film.

Next, the inside of each of the plurality of vertical holes H1 may be filled with an insulating spacer 156 and a sacrificial plug 158. In some embodiments, the insulating spacer 156 may include silicon oxide and the sacrificial plug 158 may include polysilicon, but the inventive concepts are not limited thereto.

Referring to FIGS. 31A, 31B, and 31C, a third upper insulating film UL3 may be formed to cover the respective upper surfaces of a plurality of insulating spacers 156, a plurality of sacrificial plugs 158, and the second upper insulating film UL2 in the memory cell area MEC, the dummy channel area DA, and the connection area CON.

In the resulting product in which the third upper insulating film UL3 is formed, a plurality of string select line holes may be formed by etching the third upper insulating film UL3, the second upper insulating film UL2, the first upper insulating film UL1, some of the plurality of first insulating films 132, and some of the plurality of second insulating films 134 in the memory cell area MEC, and a string select line cut structure SSLC may be formed to fill the plurality of string select line holes.

A plurality of word line cut holes WCH may be formed through the third upper insulating film UL3, the second upper insulating film UL2, the first upper insulating film UL1, the interlayer dielectric 138, the plurality of first insulating films 132, the plurality of second insulating films 134, the second conductive plate 118, and the insulating plate 112 in the memory cell area MEC, the dummy channel area DA, and the connection area CON to expose the plate common source line 110.

In the memory cell area MEC and the dummy channel area DA the insulating plate 112 may be selectively removed through an inner space of each of the plurality of word line cut holes WCH, and an empty space formed as a result may be filled with a first conductive plate 114. In the connection area CON, the insulating plate 112 may be maintained. While the insulating plate 112 in the memory cell area MEC and the dummy channel area DA is being removed, portions of a gate dielectric film 142 (which are adjacent to the insulating plate 112) of each of the plurality of dummy channel structures D140 in the memory cell area MEC and the dummy channel area DA may be removed together with the insulating plate 112, and as a result, the first conductive plate 114 may pass through a portion of the gate dielectric film 142 in the horizontal direction and contact a channel region 144.

In the memory cell area MEC, the dummy channel area DA, and the connection area CON, the plurality of second insulating films 134, the third insulating film 134R, and the sacrificial insulating ring 154 may be substituted with the plurality of gate lines 130 through the inner space of each of the plurality of word line cut holes WCH. In each of the plurality of gate lines 130, a relatively thick end portion obtained by substituting the sacrificial insulating ring 154 and both the second insulating film 134 and the third insulating film 134R contacting the sacrificial insulating ring 154 may constitute a gate pad portion 130A.

As described while the plurality of second insulating films 134, the third insulating film 134R, and the sacrificial insulating ring 154 are being substituted with the plurality of gate lines 130, after the plurality of second insulating films 134, the third insulating film 134R, and the sacrificial insulating ring 154 are removed first, before the plurality of gate lines 130 are formed, spaces in which the plurality of second insulating films 134, the third insulating film 134R, and the sacrificial insulating ring 154 have been present between each of the plurality of first insulating films 132 remain empty. In particular, in the dummy channel area DA, because spaces in which the bridge connection portion WLE (see FIGS. 5A, 5B, and 10) of each of the plurality of gate lines 130 is to be formed have relatively large planar areas as compared with other regions of the dummy channel area DA, local regions overlapping the spaces where the bridge connection portion WLE (see FIGS. 5A, 5B, and 10) is to be formed, in the vertical direction (the Z direction), in each of the plurality of first insulating films 132 may be vulnerable to collapse. However, according to the inventive concepts, in the dummy channel area DA, the offset dummy channel structure SD1 (see FIG. 10) facing and adjacent to the bridge connection portion WLE in the second horizontal direction (the Y direction) are out of the arrangement regularity of the first normal dummy channel structures DN1, which are arranged in a line in the first horizontal direction (the X direction). For example, the offset dummy channel structure SD1 may be arranged to be shifted from an imaginary first straight line toward the bridge connection portion WLE in the second horizontal direction (the Y direction), the imaginary first straight line passing through the respective centers of the first normal dummy channel structures DN1.

Therefore, even when the planar area of the bridge connection portion WLE of each of the plurality of gate lines 130 is relatively large, the bridge connection portion WLE of each of the plurality of gate lines 130, and the local regions overlapping the bridge connection portion WLE in the vertical direction (the Z direction), in each of the plurality of first insulating films 132, may be stably supported by the offset dummy channel structure SD1. Therefore, during the process of fabricating the semiconductor device 100, before the plurality of gate lines 130 are formed, structural defects, such as a pattern collapse phenomenon in which the local regions overlapping a region corresponding to the bridge connection portion WLE, in each of the plurality of first insulating films 132, collapse, may be prevented and/or the potential thereof reduced.

After the first conductive plate 114 and the plurality of gate lines 130 are formed, some of the plurality of word line cut holes WCH may each be filled with a word line cut structure WLC1, and some others of the plurality of word line cut holes WCH may each be filled with a local word line cut structure WLC2. The width of the memory cell block BLK in the second horizontal direction (the Y direction) may be defined by a plurality of word line cut structures WLC1.

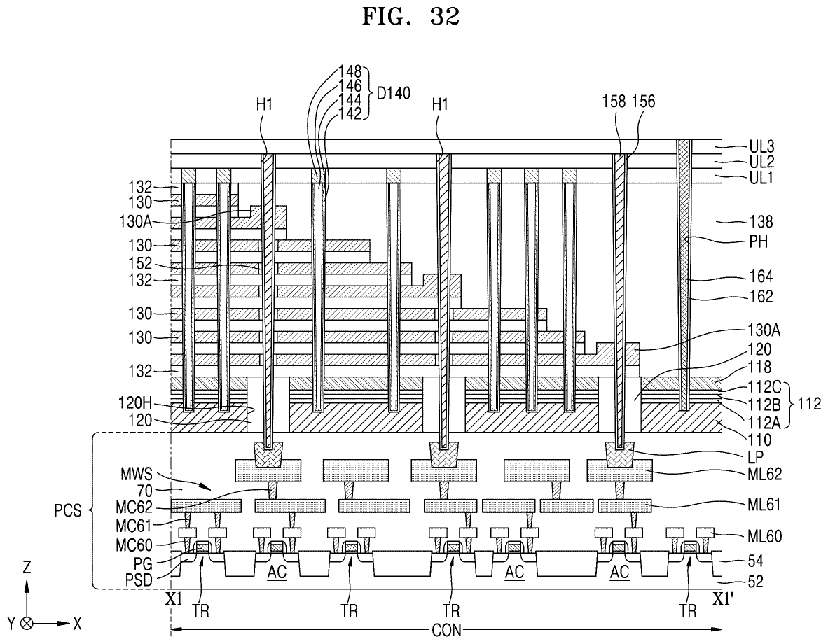

Referring to FIG. 32, in the connection area CON of the memory cell block BLK, a hole PH may be formed through the third upper insulating film UL3, the second upper insulating film UL2, the first upper insulating film UL1, the interlayer dielectric 138, the second conductive plate 118, and the insulating plate 112 to expose the plate common source line 110, and then, an insulating spacer 162 and a conductive plate contact 164 may be sequentially formed in the stated order in the hole PH.

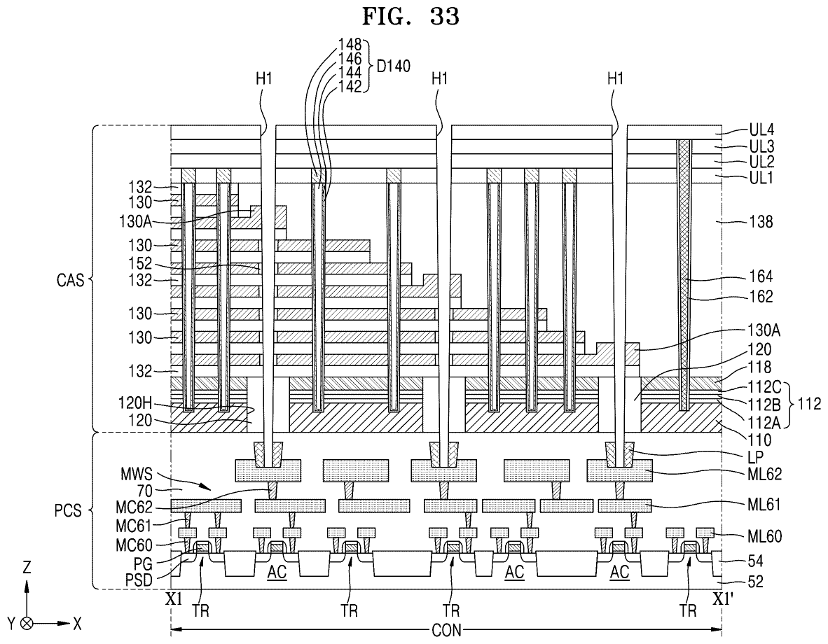

Referring to FIG. 33, a fourth upper insulating film UL4 may be formed on the resulting product having undergone the processes described with reference to FIG. 32, followed by removing a portion of each of the fourth upper insulating film UL4 and the third upper insulating film UL3, thereby exposing the insulating spacer 156 and the sacrificial plug 158. Next, the inside of each of the plurality of vertical holes H1 may be emptied by removing the insulating spacer 156 and the sacrificial plug 158, which are exposed.

Next, by etching the conductive landing pad LP exposed at the lower surface of each of the plurality of vertical holes H1, the length of each of the plurality of vertical holes H1 in the vertical direction (the Z direction) may be increased, and a wiring layer ML62 of the multilayer wiring structure MWS of the peripheral circuit structure PCS may be exposed at the lower surface of each of the plurality of vertical holes H1.

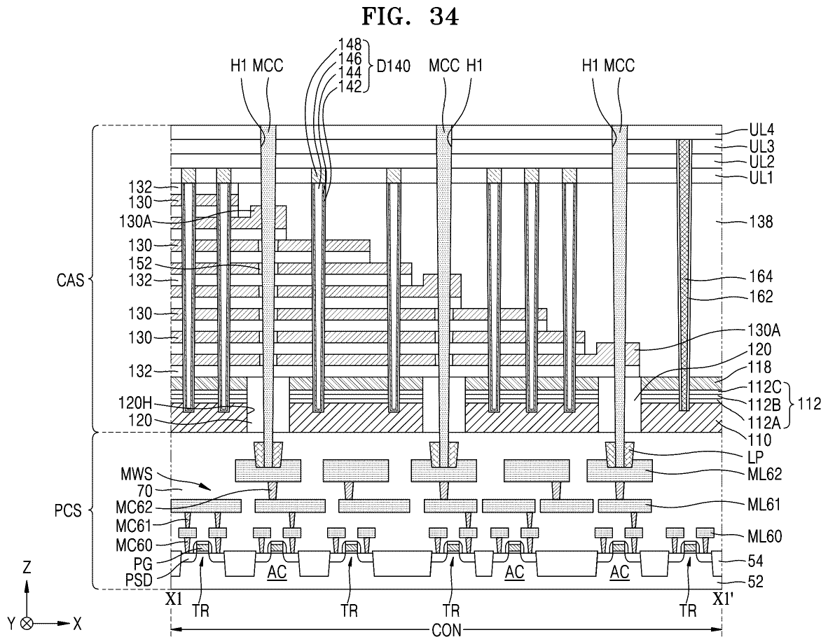

Referring to FIG. 34, in the resulting product of FIG. 33, a plurality of memory cell contacts MCC may be formed to respectively fill the plurality of vertical holes H1 in the connection area CON.

Next, as shown in FIGS. 7 to 9, a fifth upper insulating film UL5 may be formed on the resulting product of FIG. 34, and a contact plug 172, which passes through the fifth upper insulating film UL5 and the fourth upper insulating film UL4 in the connection area CON and is connected to a conductive plate contact 164, and a plurality of contact plugs 176, which pass through the fifth upper insulating film UL5, the fourth upper insulating film UL4, the third upper insulating film UL3, and the second upper insulating film UL2 in the memory cell area MEC and are respectively connected to drain regions 148 of the plurality of channel structures 140, may be formed.

Next, a plurality of upper wiring layers UML may be formed on the fifth upper insulating film UL5 in the connection area CON, and a plurality of bit lines BL may be formed on the fifth upper insulating film UL5 in the memory cell area MEC. In addition, a sixth upper insulating film UL6 may be formed to fill a space between each of the plurality of upper wiring layers UML and a space between each of the plurality of bit lines BL.

Although the method of fabricating the semiconductor device 100 described with reference to FIGS. 1 to 10 has been described with reference to FIGS. 23A to 34, it will be understood by those of ordinary skill in the art that, by making various modifications and changes to the method described with reference to FIGS. 23A to 34 without departing from the spirit and scope of the inventive concepts, the semiconductor devices 100A, 200, 300, 300A, 400, 500, 500A, and 600 described with reference to FIGS. 11 to 18 and semiconductor devices having various structures modified and changed therefrom may be fabricated.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a plurality of gate lines overlapping each other in a vertical direction, each of the plurality of gate lines having a pair of main gate portions and a bridge connection portion connecting the pair of main gate portions to each other;
a plurality of dummy channel structures passing through the plurality of gate lines in the vertical direction; and
a local word line cut structure passing through respective local regions of the plurality of gate lines in the vertical direction, the local word line cut structure intermittently extending in a first horizontal direction such that a width of the bridge connection portion is defined by the local word line cut structure in the first horizontal direction,
wherein the plurality of dummy channel structures comprise a first dummy channel structure group, the first dummy channel structure group comprising first dummy channel structures in a line extending in the first horizontal direction, the first dummy channel structures adjacent to the local word line cut structure, and
the first dummy channel structure group comprises
first normal dummy channel structures facing the local word line cut structure in a second horizontal direction that is orthogonal to the first horizontal direction, each of the first normal dummy channel structures having a center on an imaginary first straight line extending in the first horizontal direction, and
at least one offset dummy channel structure facing the bridge connection portion in the second horizontal direction and having a center at a position shifted from the imaginary first straight line toward the bridge connection portion in the second horizontal direction.

2. The semiconductor device of claim 1, wherein the plurality of dummy channel structures further comprise a second dummy channel structure group comprising second dummy channel structures on an imaginary second straight line extending in the second horizontal direction across the bridge connection portion of each of the plurality of gate lines,
the second dummy channel structure group comprises
the at least one offset dummy channel structure in one main gate portion of the pair of main gate portions, and
second normal dummy channel structures in the one main gate portion,
a distance between the second normal dummy channel and the bridge connection portion is greater than a distance between the at least one offset dummy channel structure and the bridge connection portion, and
a minimum distance between the at least one offset dummy channel structure and a second normal dummy channel structure, closest to the at least one offset dummy channel structure, from among the second normal dummy channel structures is greater than a minimum distance between two second normal dummy channel structures, adjacent to each other in the second horizontal direction, from among the second normal dummy channel structures.

3. The semiconductor device of claim 1, wherein the plurality of dummy channel structures further comprise a second dummy channel structure group comprising second dummy channel structures on an imaginary second straight line extending in the second horizontal direction across the bridge connection portion of each of the plurality of gate lines,
the second dummy channel structure group comprises
the at least one offset dummy channel structure in one main gate portion of the pair of main gate portions, and
second normal dummy channel structures in the one main gate portion,
a distance between the second normal dummy channel and the bridge connection portion is greater than a distance between the at least one offset dummy channel structure and the bridge connection portion, and
the at least one offset dummy channel structure and the second normal dummy channel structures are arranged at regular pitches in the second horizontal direction.

4. The semiconductor device of claim 1, wherein an offset minimum distance between the at least one offset dummy channel structure and the local word line cut structure is within a range of ±0.5 nm from an average minimum distance between the local word line cut structure and each of the first normal dummy channel structures adjacent to the local word line cut structure.

5. The semiconductor device of claim 1, wherein, in a plan view, the at least one offset dummy channel structure has a width in the second horizontal direction which is greater than a length in the first horizontal direction.

6. The semiconductor device of claim 1, wherein, in a plan view, a width of the at least one offset dummy channel structure in the second horizontal direction is greater than a width of each of the first normal dummy channel structures of the first dummy channel structure group in the second horizontal direction.

7. The semiconductor device of claim 1, wherein the plurality of dummy channel structures further comprise a second dummy channel structure group comprising second dummy channel structures on an imaginary second straight line extending in the second horizontal direction across the bridge connection portion of each of the plurality of gate lines,
the second dummy channel structure group comprises
the at least one offset dummy channel structure arranged in one main gate portion selected from the pair of main gate portions, and
second normal dummy channel structures arranged in the selected one main gate portion,
a distance between the second normal dummy channel structure and the bridge connection portion is greater than a distance between the at least one offset dummy channel structure and the bridge connection portion, and
in a plan view, a width of the at least one offset dummy channel structure in the second horizontal direction is greater than a length of each of the second normal dummy channel structures of the second dummy channel structure group in the second horizontal direction.

8. The semiconductor device of claim 1, wherein the plurality of dummy channel structures comprise a normal dummy channel structure group comprising third dummy channel structures respectively passing through one main gate portion selected from the pair of main gate portions of each of the plurality of gate lines in the vertical direction, and
in a plan view, the third dummy channel structures of the normal dummy channel structure group are in a matrix array structure.

9. The semiconductor device of claim 1, wherein the plurality of dummy channel structures further comprise a second dummy channel structure group comprising second dummy channel structures on an imaginary second straight line extending in the second horizontal direction across the bridge connection portion of each of the plurality of gate lines,
the second dummy channel structures of the second dummy channel structure group comprise the at least one offset dummy channel structure, and
in a plan view, other dummy channel structures among the plurality of dummy channel structures, different from the second dummy channel structures, are in a matrix array structure.

10. The semiconductor device of claim 1, wherein the first dummy channel structure group comprises a plurality of offset dummy channel structures facing the bridge connection portion in the second horizontal direction and shifted from the imaginary first straight line toward the bridge connection portion in the second horizontal direction, and
respective centers of the plurality of offset dummy channel structures are in a straight line extending in the first horizontal direction.

11. A semiconductor device comprising:
a plurality of gate lines extending across a memory cell area, a dummy channel area, and a connection area, the memory cell area, the dummy channel area, and the connection area sequentially arranged in a first horizontal direction in a memory cell block, the plurality of gate lines overlapping each other in a vertical direction;
a plurality of channel structures passing through the plurality of gate lines in the vertical direction in the memory cell area;
a plurality of dummy channel structures passing through the plurality of gate lines in the vertical direction in the dummy channel area;
a pair of word line cut structures extending lengthwise in the first horizontal direction and defining a width of the memory cell block in a second horizontal direction, the second horizontal direction orthogonal to the first horizontal direction; and
a local word line cut structure between the pair of word line cut structures, the local word line cut structure passing through respective local regions of the plurality of gate lines in the vertical direction and intermittently extending in the first horizontal direction,
wherein each of the plurality of gate lines comprises
a pair of main gate portions respectively contacting the pair of word line cut structures, and
a bridge connection portion connecting the pair of main gate portions to each other in the dummy channel area, the bridge connection portion having a width defined in the first horizontal direction by the local word line cut structure,
the plurality of dummy channel structures in the dummy channel area comprise a first dummy channel structure group comprising first dummy channel structures in a line in the first horizontal direction adjacent to the local word line cut structure, and
the first dummy channel structure group comprises
first normal dummy channel structures facing the local word line cut structure in the second horizontal direction, each of the first normal dummy channel structures having a center on an imaginary first straight line extending in the first horizontal direction, and
an offset dummy channel structure facing the bridge connection portion in the second horizontal direction and having a center at a position shifted from the imaginary first straight line toward the bridge connection portion in the second horizontal direction.

12. The semiconductor device of claim 11, wherein the plurality of dummy channel structures in the dummy channel area further comprise a second dummy channel structure group comprising second dummy channel structures on an imaginary second straight line extending in the second horizontal direction across the bridge connection portion of each of the plurality of gate lines,
the second dummy channel structure group comprises
the offset dummy channel structure, and
second normal dummy channel structures,
a distance between the second normal dummy channel structure and the bridge connection portion is greater than a distance between the offset dummy channel structure and the bridge connection portion, and
a minimum distance between the offset dummy channel structure and a second normal dummy channel structure closest to the offset dummy channel structure from among the second normal dummy channel structures is greater than a minimum distance between two adjacent second normal dummy channel structures from among the second normal dummy channel structures.

13. The semiconductor device of claim 11, wherein the plurality of dummy channel structures in the dummy channel area further comprise a second dummy channel structure group comprising second dummy channel structures on an imaginary second straight line extending in the second horizontal direction across the bridge connection portion of each of the plurality of gate lines,
the second dummy channel structure group comprises
the offset dummy channel structure, and
second normal dummy channel structures,
a distance between the second normal dummy channel and the bridge connection portion is greater than a distance between the offset dummy channel structure and the bridge connection portion, and
the offset dummy channel structure and the second normal dummy channel structures are arranged at regular pitches in the second horizontal direction.

14. The semiconductor device of claim 11, wherein an offset minimum distance between the offset dummy channel structure and the local word line cut structure is within a range of ±0.5 nm from an average minimum distance between the local word line cut structure and each of the first normal dummy channel structures adjacent to the local word line cut structure.

15. The semiconductor device of claim 11, wherein, in a plan view, the offset dummy channel structure has a width in the second horizontal direction which is greater than a length thereof in the first horizontal direction.

16. The semiconductor device of claim 11, wherein, in a plan view, a width of the offset dummy channel structure in the second horizontal direction is greater than a width of each of the first normal dummy channel structures of the first dummy channel structure group in the second horizontal direction.

17. The semiconductor device of claim 11, wherein the plurality of dummy channel structures in the dummy channel area further comprise a second dummy channel structure group comprising second dummy channel structures on a line along an imaginary second straight line extending in the second horizontal direction across the bridge connection portion of each of the plurality of gate lines,
the second dummy channel structure group comprises
the offset dummy channel structure, and
second normal dummy channel structures,
a distance between the second normal dummy channel structure and the bridge connection portion is greater than a distance between the offset dummy channel structure and the bridge connection portion, and
in a plan view, a width of the offset dummy channel structure in the second horizontal direction is greater than a length of each of the second normal dummy channel structures of the second dummy channel structure group in the second horizontal direction.

18. The semiconductor device of claim 11, wherein the plurality of dummy channel structures in the dummy channel area comprise a normal dummy channel structure group comprising third dummy channel structures between the local word line cut structure and each of the pair of word line cut structures, the third dummy channel structures respectively passing through one main gate portion selected from the pair of main gate portions of each of the plurality of gate lines in the vertical direction, and
in a plan view, the third dummy channel structures of the normal dummy channel structure group are in a matrix array structure.

19. The semiconductor device of claim 11, wherein the plurality of dummy channel structures in the dummy channel area further comprises a second dummy channel structure group comprising second dummy channel structures on a line along an imaginary second straight line extending in the second horizontal direction across the bridge connection portion of each of the plurality of gate lines,
the second dummy channel structures of the second dummy channel structure group comprise the offset dummy channel structure, and
in a plan view, other dummy channel structures among the plurality of dummy channel structures, different from the second dummy channel structures, are in a matrix array structure.

20. An electronic system comprising:
a main substrate;
a semiconductor device on the main substrate; and
a controller on the main substrate and electrically connected to the semiconductor device,
wherein the semiconductor device comprises
a plurality of gate lines overlapping each other in a vertical direction;
a plurality of dummy channel structures passing through the plurality of gate lines in the vertical direction, and
a local word line cut structure passing through respective local regions of the plurality of gate lines in the vertical direction and intermittently extending in a first horizontal direction,
the plurality of dummy channel structures comprise a first dummy channel structure group, the first dummy channel structure group comprising first dummy channel structures in a line extending in the first horizontal direction, the first dummy channel structures adjacent to the local word line cut structure, and
the first dummy channel structure group comprises
first normal dummy channel structures facing the local word line cut structure in a second horizontal direction that is orthogonal to the first horizontal direction, each of the first normal dummy channel structures having a center on an imaginary first straight line extending in the first horizontal direction, and
at least one offset dummy channel structure facing a bridge connection portion in the second horizontal direction and having a center at a position shifted from the imaginary first straight line toward the bridge connection portion in the second horizontal direction.
